(19) United States
(12) Patent Application Publication
(10) Pub. No.: US 2026/0292370 A1
(43) Pub. Date: Sep. 24, 2026

(54) IMAGE SENSOR OUTPUTTING PHASE DATA AND HIGH DYNAMIC RANGE IMAGE

(71) Applicant: SAMSUNG ELECTRONICS CO., LTD., Suwon-si (KR)

(72) Inventors: Se-Hwan YUN, Suwon-si (KR); TAE-SHICK WANG, Suwon-si (KR); JAESEONG YU, Suwon-si (KR); JEONGGUK LEE, Suwon-si (KR)

(73) Assignee: SAMSUNG ELECTRONICS CO., LTD., Suwon-si (KR)

(21) Appl. No.: 19/444,935

(22) Filed: Jan. 9, 2026

(30) Foreign Application Priority Data
Mar. 20, 2025 (KR) 10-2025-0036142

(51) Int. Cl. H04N 25/78; H04N 25/57

(52) U.S. Cl. CPC H04N 25/78; H04N 25/57

(57) ABSTRACT

An image sensor is provided. The image sensor includes a pixel array including a plurality of pixels; a readout circuit configured to digitally convert pixel signals of the plurality of pixels to a plurality of image signals; and an image processing circuit configured to output high dynamic range (HDR) image data and phase data based on the plurality of image signals. The plurality of pixels includes a first pixel and a second pixel. Each of the first pixel and the second pixel includes sub-pixels sharing a microlens, each of the sub-pixels including a photoelectric element and a transfer transistor connecting the photoelectric element to a floating diffusion node. In each of the first pixel and the second pixel, a subset of sub-pixels at the same position with respect to the microlens, is configured to receive control signals of the transfer transistor through different interconnections.

### CROSS-REFERENCE TO RELATED APPLICATION

This application claims priority to Korean Patent Application No. 10-2025-0036142 filed on Mar. 20, 2025, the disclosure of which is herein incorporated by reference in its entirety.

### BACKGROUND

### 1. Field

The present disclosure relates to an image sensor, and more particularly, to an image sensor generating a high dynamic range (HDR) image and phase data.

### 2. Description of Related Art

An image sensor may be a device configured to convert optical signals into electrical signals. Examples of image sensors may include charge coupled device (CCD) image sensors and complementary metal oxide semiconductor (CMOS) image sensors. Image sensors may be configured to generate phase data for use in autofocusing (AF). For example, in phase difference auto focusing (PDAF), an application processor may adjust a focal length based on a phase difference between optical signals detected by pixels disposed at different positions. Dynamic range of the sensors and image quality may be increased.

### SUMMARY

One or more embodiments of the present disclosure may include an image sensor configured to generate HDR images and to reliably generate phase data across a wide dynamic range.

According to an aspect of one or more embodiments, an image sensor may comprise a pixel array comprising a plurality of pixels; a readout circuit configured to digitally convert pixel signals of the plurality of pixels to a plurality of image signals; and an image processing circuit configured to output high dynamic range (HDR) image data and phase data based on the plurality of image signals. The plurality of pixels may comprise a first pixel and a second pixel. Each of the first pixel and the second pixel may comprise sub-pixels sharing a microlens, each of the sub-pixels comprising a photoelectric element and a transfer transistor connecting the photoelectric element to a floating diffusion node. In each of the first pixel and the second pixel, a subset of sub-pixels at the same position with respect to the microlens, may be configured to receive control signals of the transfer transistor through different interconnections.

According another aspect of one or more embodiments, an image sensor may comprise a pixel array comprising a plurality of pixels; a readout circuit configured to digitally convert pixel signals of the plurality of pixels to image signals; and an image processing circuit configured to output high dynamic range (HDR) image data and phase data based on the image signals. The plurality of pixels may comprise a first pixel and a second pixel. Each of the first pixel and the second pixel may comprise sub-pixels sharing a microlens, each of the sub-pixels comprising a photoelectric element and a transfer transistor configured to connect the photoelectric element to a floating diffusion node. At least one sub-pixel of the first pixel may be configured not to output a pixel signal during both a first readout period and a second readout period. Each sub-pixel of the second pixel may be configured to output the pixel signal during at least one of the first readout period or the second readout period.

According another aspect of one or more embodiments, an image sensor may comprise a pixel array comprising a plurality of pixel groups; a readout circuit configured to digitally convert pixel signals from the pixel array to image signals; and an image processing circuit configured to output high dynamic range (HDR) image data and phase data based on the image signals. Each of the plurality of pixel groups may comprise a plurality of first pixels and a plurality of second pixels. Each of the plurality of first pixels and each of the plurality of second pixels may comprise sub-pixels sharing a microlens, each of the sub-pixels comprising a photoelectric element and a transfer transistor connecting the photoelectric element to a floating diffusion node. A first sub-pixel of each of the plurality of first pixels may be configured to output a pixel signal during at least one of a first readout period and a second readout period, and a second sub-pixel of each of the plurality of first pixels is configured not to output a pixel signal during both the first readout period and the second readout period. Sub-pixels of each of the plurality of second pixels may be configured to output a pixel signal during at least one of the first readout period and the second readout period.

### BRIEF DESCRIPTION OF DRAWINGS

Various techniques will be described with reference to the drawings, in which:

FIG. 1 is an example diagram illustrating an image sensor according to one or more embodiments;

FIG. 2 is an example diagram illustrating a method of generating phase data based on a first pixel and a second pixel by an image signal processor according to one or more embodiments;

FIG. 3 is an example diagram illustrating image signals used to generate HDR image data and phase data according to one or more embodiments;

FIG. 4 is an example diagram illustrating a method of generating HDR image data by an image signal processor according to one or more embodiments;

FIG. 5 is an example diagram illustrating a method of generating phase data by an image signal processor according to one or more embodiments;

FIGS. 6A to 6D are example diagrams illustrating pixels according to embodiments according to one or more embodiments;

FIG. 7 is an example circuit diagram of a pixel according to an embodiment according to one or more embodiments;

FIG. 8 is an example timing diagram illustrating the operation of a pixel in a first mode according to one or more embodiments described in conjunction with at least FIG. 7;

FIG. 9 is an example diagram illustrating a first pixel according to one or more embodiments;

FIGS. 10 and 11 are example diagrams illustrating a pixel group including a first pixel according to one or more embodiments;

FIGS. 12 and 13 are example diagrams, respectively illustrating a first readout operation and a second readout operation of a pixel group including a first pixel according to one or more embodiments described in conjunction with at least FIG. 9;

FIG. 14 is an example diagram illustrating an example of interconnections for controlling a first pixel according to one or more embodiments described in conjunction with at least FIG. 9;

FIGS. 15 and 16 are example diagrams illustrating a first readout operation and a second readout operation of a first pixel according to one or more embodiments described in conjunction with at least FIG. 9;

FIGS. 17A and 17B are example diagrams illustrating phase data of an image sensor according to one or more embodiments;

FIG. 18 is an example diagram illustrating a first pixel according to one or more embodiments;

FIGS. 19 and 20 are example diagrams, respectively illustrating a first readout operation and a second readout operation of a pixel group including a first pixel according to one or more embodiments described in conjunction with at least FIG. 18;

FIGS. 21 to 28 are example diagrams illustrating example of interconnections for controlling a first pixel and readout operations of the first pixel according to one or more embodiments described in conjunction with FIG. 18;

FIG. 29 is an example diagram illustrating phase data of an image sensor including a first pixel according to one or more embodiments described in conjunction with FIG. 18;

FIG. 30 is an example diagram illustrating a first readout operation of a pixel group including a first pixel according to one or more embodiments described in conjunction with FIG. 9;

FIGS. 31 to 34 are example diagrams illustrating examples of interconnections for controlling a first pixel and readout operations of the first pixel according to one or more embodiments described in conjunction with FIG. 9;

FIG. 35 is an example diagram illustrating phase data generated based on the operations described in conjunction with at least FIGS. 30 to 34;

FIG. 36 is an example diagram illustrating a first readout operation of a pixel group including a first pixel according to one or more embodiments described in conjunction with FIG. 9;

FIG. 37 is an example diagram illustrating a method of generating phase data based on a first readout by an image signal processor according to one or more embodiments described in conjunction with FIG. 36;

FIGS. 38 and 39 are example diagrams illustrating a first readout operation and a second readout operation of a pixel group according to one or more embodiments described in conjunction with at least FIGS. 36 and 37.

FIG. 40 is an example diagram illustrating pixel units, each including a first pixel according to one or more embodiments;

FIGS. 41 and 42 are example diagrams illustrating a first readout operation and a second readout operation of pixel units according to one or more embodiments described in conjunction with FIG. 40;

FIG. 43 is an example diagram illustrating pixel units, each including a first pixel according to one or more embodiments;

FIGS. 44 and 45 are example diagrams illustrating a first readout operation and a second readout operation of pixel units according to one or more embodiments described in conjunction with FIG. 43;

FIG. 46 is an example diagram illustrating pixel units, each including a first pixel according to one or more embodiments;

FIGS. 47 and 48 are example diagrams illustrating a first readout operation and a second readout operation of pixel units according to one or more embodiments described in conjunction with FIG. 46;

FIG. 49 is an example diagram illustrating pixel units, each including a first pixel according to one or more embodiments; and

FIGS. 50 and 51 are example diagrams illustrating a first readout operation and a second readout operation of pixel units according to one or more embodiments of FIG. 49.

### DETAILED DESCRIPTION

The following description with reference to the accompanying drawings is provided to assist in a comprehensive understanding of various embodiments of the present disclosure.

Use of terms such as “a” and “an” and “the” and similar referents in context of describing disclosed embodiments (especially in context of following claims) are to be construed to cover both singular and plural, unless otherwise indicated herein or clearly contradicted by context, and not as a definition of a term.

As used herein, such an expression as “comprises,” “has,” “consists,” or “include,” or the like should not be interpreted to necessarily include all elements or all operations described in the specification, and should be interpreted to be allowed to exclude some of them or further include additional elements or operations.

Terms such as “first,” “second,” “third,” “fourth,” etc. are used merely to distinguish elements from one another and thus do not denote any particular order unless an order is specifically described. For example, the term “second” may be used without using the term “first”. Also, although the terms “first,” “second,” “third,” and so on may be used herein to describe various elements, components, regions, layers and/or sections, these elements, components, regions, layers and/or sections should not be limited by these terms.

It should be understood that when an element is referred to as being “connected” or “coupled” to another element, it may be connected or coupled directly to the other element, or any other element may be interposer between them. In contrast, it should be understood that when an element is referred to as being “directly connected” or “directly coupled” to another element, there are no element interposed between them.

Phrases of form such as “at least one of A, B, and C,” or “at least one of A, B or C,” unless specifically stated otherwise or otherwise clearly contradicted by context, is otherwise understood with context as used in general to present that an item, term, etc., may be either A or B or C, or any nonempty subset of set of A and B and C. For instance, in illustrative example of a set having three members, conjunctive phrases “at least one of A, B, and C” and “at least one of A, B or C” refer to any of following sets: {A}, {B}, {C}, {A, B}, {A, C}, {B, C}, {A, B, C}. Thus, such language is not generally intended to imply that certain embodiments require at least one of A, at least one of B and at least one of C each to be present.

Terms such as “set” (e.g., “a set of items”) or “subset” unless otherwise noted or contradicted by context, is to be construed as a nonempty collection comprising one or more members. Further, unless otherwise noted or contradicted by context, term “subset” of a corresponding set does not necessarily denote a proper subset of corresponding set, but subset and corresponding set may be equal.

In addition, unless otherwise noted or contradicted by context, term “plurality” indicates a state of being plural (e.g., “a plurality of items” indicates multiple items). Number of items in a plurality is at least two, but can be more when so indicated either explicitly or by context. Further, unless stated otherwise or otherwise clear from context, phrase “based on” means “based at least in part on” and not “based solely on.”

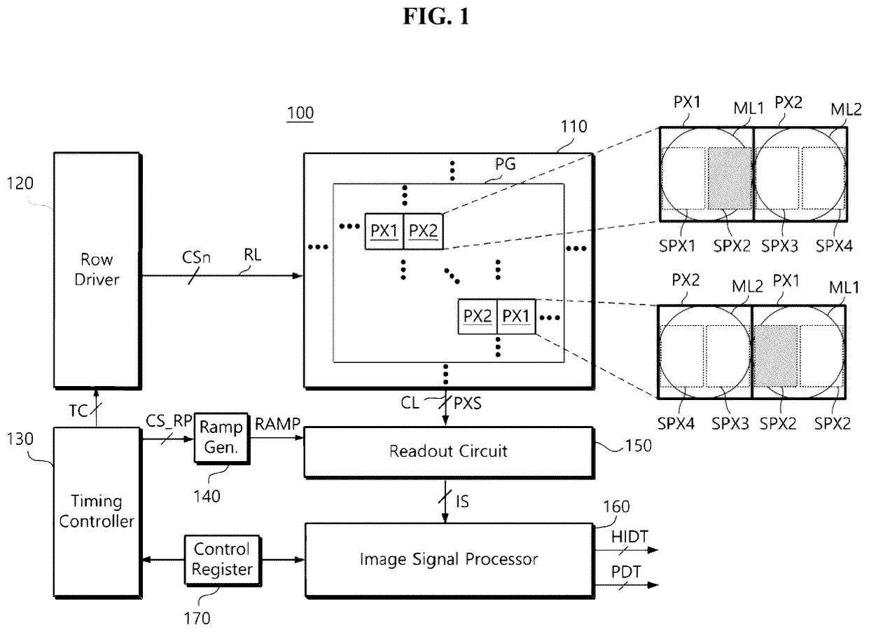

FIG. 1 is an example diagram illustrating an image sensor 100 according to one or more embodiments.

The pixel array 110 according to an embodiment may include a first pixel PX1 and a second pixel PX2. The image sensor 100 may control the first pixel PX1 and the second pixel PX2 differently in a specific mode. For example, a second sub-pixel SPX2 of the first pixel PX1 may not output a pixel signal in all of a plurality of readout periods of a specific mode. The second sub-pixel SPX2 of the first pixel PX1 may be referred to as a sub-pixel electrically disabled in the specific mode.

For example, when a certain sub-pixel outputs a pixel signal, at least a portion of the pixel signal output from the pixel array may be based on photocharges generated by the sub-pixel.

Sub-pixels indicated by dashed lines in FIGS. 1 to 4 may represent conceptual sub-pixels and do not indicate the number or positions of sub-pixels. For example, FIG. 1 does not necessarily indicate that each of the sub-pixels SPX1, SPX2, SPX3, and SPX4 consists of only one sub-pixel. FIG. 1 should not be interpreted as indicating only that the first sub-pixel SPX1 and the second sub-pixel SPX2 are laterally symmetric with respect to a microlens ML1. FIG. 1 should not be interpreted as indicating only that the third sub-pixel SPX3 and the fourth sub-pixel SPX4 are laterally symmetric with respect to a microlens ML2.

The image sensor 100 according to an embodiment is described in detail with reference to FIG. 1.

Referring to FIG. 1, the image sensor 100 may include a pixel array 110, a row driver 120, a timing controller 130, a ramp generator 140, a readout circuit 150, an image signal processor 160, and a control register 170.

The pixel array 110 may include a plurality of pixels. The plurality of pixels may, for example, be arranged in a matrix. The pixel array 110 may receive a plurality of pixel driving signals CSn, such as a select signal, a reset signal, and a transfer control signal, from the row driver 120. The pixel array 110 may operate under the control of the received pixel driving signals CSn.

A photoelectric conversion element may be a photodiode (PD). The photodiode (PD) may refer to a type of photoelectric conversion element that generates and accumulates charges in proportion to an optical signal incident on each pixel. The photoelectric conversion element may be a photodiode (PD), a photocapacitor, a photogate, a pinned photodiode (PPD), a partially pinned photodiode, an organic photodiode (OPD), a quantum dot (QD), or combinations thereof. According to one or more embodiments, the photoelectric conversion element may be the photodiode (PD). However, other photoelectric conversion elements, including those mentioned above, may be used as the photoelectric conversion element, and the photoelectric conversion element may not be limited to the photodiode (PD).

Each pixel of the image sensor 100 may convert an optical signal into a pixel signal PXS, which is an electrical signal, using the photoelectric conversion element. The pixel signal PXS may be provided to the readout circuit 150 through a plurality of column lines CL. The readout circuit 150 may include an analog-to-digital converter converting the pixel signal PXS into a digital image signal IS.

The image signal processor 160 may process the image signal IS to generate HDR image data HIDT and phase data PDT. The HDR image data HIDT and phase data PDT may be output to an interface circuit. The interface circuit may output the HDR image data HIDT and phase data PDT to an external entity. For example, the interface circuit may transmit the HDR image data HIDT and phase data PDT to an application processor.

The image sensor 100 may operate in a plurality of modes based on control information stored in the control register 170. For example, the control register 170 may store mode information received from an external device through the interface circuit.

The row driver 120 according to an embodiment may generate pixel driving signals CSn to control the pixels PX1 and PX2 based on the control information.

For example, the row driver 120 may generate pixel driving signals CSn to control the pixels PX1 and PX2 differently in different modes.

For example, in a first mode, the row driver 120 may generate pixel driving signals CSn to control the transfer of photocharges from each of the sub-pixels SPX1, SPX2, SPX3, and SPX4 of the pixels PX1 and PX2 to a floating diffusion node. In a second mode, the row driver 120 may generate pixel driving signals CSn to control a portion of the sub-pixels SPX1, SPX2, SPX3, and SPX4 of the pixels PX1 and PX2 to prevent the photocharges from being transferred to the floating diffusion node during all readout periods.

The image signal processor 160 may generate HDR image data HIDT and phase data PDT based on the control information. For example, the image signal processor 160 may generate HDR image data HIDT and phase data PDT in different ways in different modes.

The pixel array 110 according to an embodiment may include a plurality of pixel groups PGs. Each of the pixel groups PGs may include a plurality of pixels.

A pixel group PG may include a first pixel PX1 and a second pixel PX2. The pixel group PG may include a plurality of first pixels PX1 and a plurality of second pixels PX2. The pixel group PG may include a number of second pixels PX2, equal to or greater than the number of first pixels PX1.

One of the plurality of first pixels PX1 may be disposed in the same row as one of the plurality of second pixels PX2.

The first pixel PX1 and the second pixel PX2 may include microlenses ML1 and ML2, respectively.

The first pixel PX1 and the second pixel PX2 may each include sub-pixels sharing the microlenses ML1 and ML2. The first pixel PX1 and the second pixel PX2 may each include a plurality of sub-pixels. For example, the first pixel PX1 may include a first sub-pixel SPX1 and a second sub-pixel SPX2, and the second pixel PX2 may include a third sub-pixel SPX3 and a fourth sub-pixel SPX4.

In one or more embodiments, in each of the first pixels PX1 disposed in different rows, the position of the second sub-pixel SPX2 may vary with respect to the microlens ML1.

In one or more embodiments, each of the first sub-pixel SPX1, the second sub-pixel SPX2, the third sub-pixel SPX3, and the fourth sub-pixel SPX4 may include at least one sub-pixel. For example, each of the first sub-pixel SPX1, the second sub-pixel SPX2, the third sub-pixel SPX3, and the fourth sub-pixel SPX4 may include a plurality of sub-pixels.

In one or more embodiments, at least one of the first sub-pixel SPX1, the second sub-pixel SPX2, the third sub-pixel SPX3, and the fourth sub-pixel SPX4 may include a plurality of sub-pixels. For example, the first pixel PX1 may include a plurality of first sub-pixels SPX1 and a plurality of second sub-pixels SPX2. Alternatively, the first pixel PX1 may include a plurality of first sub-pixels SPX1 and a single second sub-pixel SPX2.

With respect to the microlens ML1, a position of the first sub-pixel SPX1 may correspond to a position of the third sub-pixel SPX3 and a position of the second sub-pixel SPX2 may correspond to a position of the fourth sub-pixel SPX4. The number of third sub-pixels SPX3 may be the same as the number of first sub-pixels SPX1, and the number of fourth sub-pixels SPX4 may be the same as the number of second sub-pixels SPX2.

Each of the sub-pixels SPX1, SPX2, SPX3, and SPX4 of the first pixel PX1 and the second pixel PX2 may include a photoelectric element and a transfer transistor connecting the photoelectric element to a floating diffusion node.

In one or more embodiments, in a second mode, the first pixel PX1 and the second pixel PX2 may be controlled differently by the row driver 120. The first pixel PX1 and the second pixel PX2 may operate differently based on the pixel driving signal CSn of the row driver 120.

For example, in the second mode, the first sub-pixel SPX1 of the first pixel PX1 may output a pixel signal in at least one of a first readout period and a second readout period, and each of the sub-pixels SPX3 and SPX4 of the second pixel PX2 may output a pixel signal in at least one of the first readout period and the second readout period. The second sub-pixel SPX2 of the first pixel PX1 may not output a pixel signal in both the first readout period and the second readout period. For example, the second sub-pixel SPX2 of the first pixel PX1 may be electrically controlled to prevent outputting a pixel signal in both the first readout period and the second readout period.

In one or more embodiments, in a first mode, sub-pixels at the same position with respect to a microlens in the first pixel PX1 and the second pixel PX2, which are disposed in the same row, may operate in the same manner. For example, the first pixel PX1 and the second pixel PX2 may be disposed in the same row, the first sub-pixel SPX1 and the third sub-pixel SPX3 may be disposed at the same position with respect to the microlens in the first pixel PX1 and the second pixel PX2. In the first mode, the first sub-pixel SPX1 and the third sub-pixel SPX3 may output pixel signals in the same readout period, and the second sub-pixel SPX2 and the fourth sub-pixel SPX4 may output pixel signals in the same readout period.

In one or more embodiments, in the second mode, a portion of the sub-pixels at the same position with respect to the microlens in the first pixel PX1 and the second pixel PX2 may receive control signals (transfer control signals) for the transfer transistor through different interconnections.

For example, even when the first pixel PX1 and the second pixel PX2 are disposed in the same row, the first sub-pixel SPX1 of the first pixel PX1 and the third sub-pixel SPX3 of the second pixel PX2 may receive transfer control signals through the same interconnection, while the second sub-pixel SPX2 of the first pixel PX1 and the fourth sub-pixel SPX4 of the second pixel PX2 may receive transfer control signals through different interconnections. Alternatively, all of the first sub-pixel SPX1, the second sub-pixel SPX2, the third sub-pixel SPX3, and the fourth sub-pixel SPX4 may receive transfer control signals through different interconnections.

In one or more embodiments, in the second mode, the image signal processor 160 may generate phase data PDT differently based on control information. For example, the image signal processor 160 may generate one type of phase data in the first mode and two types of phase data in the second mode. Alternatively, the image signal processor 160 may generate one type of phase data in the first mode and a different type of phase data in the second mode.

In the second mode, the image signal processor 160 may generate phase data based on the pixel signal of the first sub-pixel SPX1 of the first pixel PX1. The first sub-pixel SPX1 of the first pixel PX1 may output an unsaturated pixel signal across a wide dynamic range. For example, the first sub-pixel SPX1 of the first pixel PX1 may output an unsaturated pixel signal from low to high light brightness. Accordingly, the image sensor 100 may reliably generate phase data in a wide dynamic range.

An electronic device may accurately perform autofocusing in a wide dynamic range using the phase data of the image sensor 100. For example, even in very bright environments, the image sensor 100 may generate phase data based on unsaturated pixel signals, and the electronic device may accurately perform autofocusing.

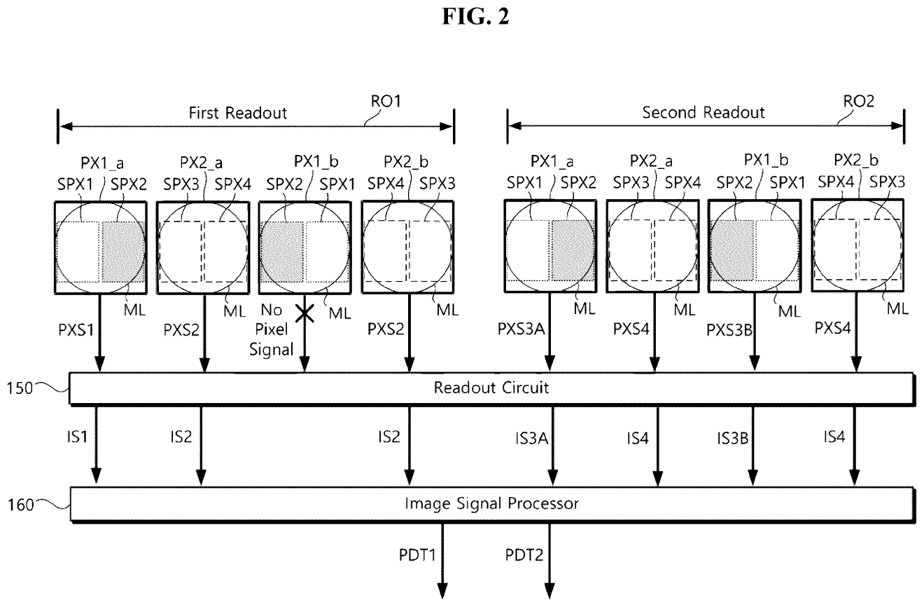

FIG. 2 is an example diagram illustrating a method of generating phase data based on a first pixel and a second pixel by the image signal processor 160 of FIG. 1.

First pixels PX1_a and PX1_b of FIG. 2 may correspond to the first pixel PX1 of FIG. 1. Second pixels PX2_a and PX2_b of FIG. 2 may correspond to the second pixel PX2 of FIG. 1.

The method of generating phase data PDT1 and PDT2, described with reference to FIG. 2, may be performed in a specific mode. For example, the method of FIG. 2 may be performed in a high-speed shooting mode.

In one or more embodiments, the image sensor 100 may generate a plurality of pieces of phase data PDT1 and PDT2.

The readout circuit 150 may read pixel signals of pixels in a single frame through a plurality of readout operations RO1 and RO2.

For example, the readout circuit 150 may read pixel signals based on a subset of sub-pixels of each pixel in a first readout operation RO1 and read pixel signals based on all sub-pixels of each pixel in a second readout operation RO2.

An electrically disabled sub-pixel according to an embodiment may not output a pixel signal in both the first readout operation RO1 and the second readout operation RO2.

The image signal processor 160 may generate a plurality of pieces of phase data PDT1 and PDT2 using at least a portion of the image signals IS1, IS2, IS3A, IS3B, and IS4 generated based on the plurality of readout operations RO1 and RO2.

In one or more embodiments, the positions of the second sub-pixels SPX2 in the first pixels PX1_a and PX1_b may be different from each other. For example, the second sub-pixel SPX2 of one first pixel PX1_a and the second sub-pixel SPX2 of another first pixel PX1_b may be disposed to be symmetric with respect to a microlens.

In one or more embodiments, a sub-pixel of one of the first pixels PX1_a and PX1_b may not output a pixel signal in both the first readout operation RO1 and the second readout operation RO2. For example, the second sub-pixel SPX2 of the first pixels PX1_a and PX1_b may not output a pixel signal in both the first readout operation RO1 and the second readout operation RO2. In contrast, the sub-pixels PX2_a and PX2_b of the second pixels PX2_a and PX2_b may output a pixel signal in at least one of the first readout operation RO1 and the second readout operation RO2.

Referring to FIG. 2, in the first readout operation RO1, the first pixel PX1_a and the second pixels PX2_a and PX2_b may output pixel signals, while the first pixel PX1_b may not output a pixel signal. For example, the first pixel PX1_a may output a first pixel signal PXSI based only on the first sub-pixel SPX1. The second pixel PX2_a may output a second pixel signal PXS2 based only on the third sub-pixel SPX3. The second pixel PX2_b may output a second pixel signal PXS2 based only on the fourth sub-pixel SPX4.

For example, in the first readout operation RO1, each of the pixels PX1_a, PX1_b, PX2_a, and PX2_b may output a pixel signal based on a portion of sub-pixels at the same position, excluding electrically disabled sub-pixels.

Referring to FIG. 2, in the second readout operation RO2, the first pixels PX1_a and PX1_b and the second pixels PX2_a and PX2_b may output pixel signals. For example, the first pixel PX1_a may output a third pixel signal PXS3 based only on the first sub-pixel SPX1. The second pixels PX2_a and PX2_b may output a fourth pixel signal PX4 based on all sub-pixels SPX3 and SPX4. The first pixel PX1_b may output a third pixel signal PXS3 based only on the first sub-pixel SPX1.

For example, in the second readout operation RO2, each of the pixels PX1_a, PX1_b, PX2_a, and PX2_b may output a pixel signal based on all sub-pixels, excluding electrically disabled sub-pixels.

The image signal processor 160 may generate second phase data PDT2 based on the pixel signals PXS2 and PXS4 of the second pixels PX2_a and PX2_b.

For example, the image signal processor 160 may generate a portion of the second phase data PDT2 based on a second image signal IS2 based on the second pixel signal PXS2. The image signal processor 160 may generate another portion of the second phase data PDT2 by subtracting the image signal, generated based on the second image signal IS2, from a fourth image signal IS4 based on the fourth pixel signal PXS4.

The image signal processor 160 may generate first phase data PDT1 based only on the third pixel signals PXS3A and PXS3B read in the second readout operation RO2 among the pixel signals PXS1, PXS3A, and PXS3B of the first pixels PX1_a and PX1_b. The image signal processor 160 may not use the pixel signal PXS1, read in the first readout operation RO1, for generating the first phase data PDT1.

For example, the image signal processing circuit 160 may generate a third image signal IS3A, based on a third pixel signal PXS3A, as a portion of the first phase data PDT1, and may generate another third image signal IS3B, based on another third pixel signal PXS3B, as another portion of the first phase data PDT1.

According to one or more embodiments, the first phase data PDT1 may be generated based on pixel signals PXS3A and PXS3B output only by a subset of sub-pixels SPX1 of the first pixels PX1_a and PX1_b. Accordingly, the pixel signals PXS3A and PXS3B may not be saturated in a wide dynamic range. As a result, the first phase data PDT1 may be reliably generated in a wide dynamic range.

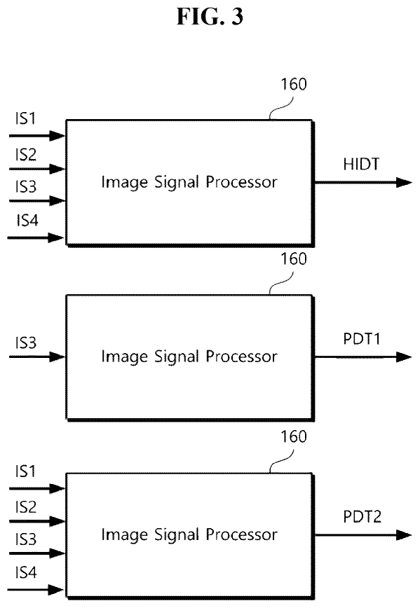

FIG. 3 is an example diagram illustrating image signals used to generate HDR image data HIDT and phase data PDT1 and PDT2 in the second mode.

The image signals used to generate HDR image data HIDT and phase data PDT1, PDT2 are described with reference to FIGS. 1 and 3.

At least one first pixel PX1 may output a pixel signal in the first readout operation. The readout circuit 150 of FIG. 1 may output a first image signal IS1 based on the pixel signal of the first pixel PX1 output in the first readout operation.

The first pixel PX1 may output a pixel signal in the second readout operation. The readout circuit 150 of FIG. 1 may output a third image signal IS3 based on the pixel signal of the first pixel PX1 output in the second readout operation.

The second pixel PX2 may output pixel signals in both the first readout operation and the second readout operation. The readout circuit 150 of FIG. 1 may output a second image signal IS2 and a fourth image signal IS4 based on the pixel signals, respectively output from the second pixel PX2 in the first readout operation and the second readout operation.

The image signal processor 160 according to an embodiment may generate HDR image data HIDT based on a first image signal IS1, a second image signal IS2, a third image signal IS3, and a fourth image signal IS4.

The image signal processor 160 may generate first phase data PDT1 based solely on the third image signal IS3.

The image signal processor 160 may generate second phase data PDT2 based on the first image signal IS1, the second image signal IS2, the third image signal IS3, and the fourth image signal IS4.

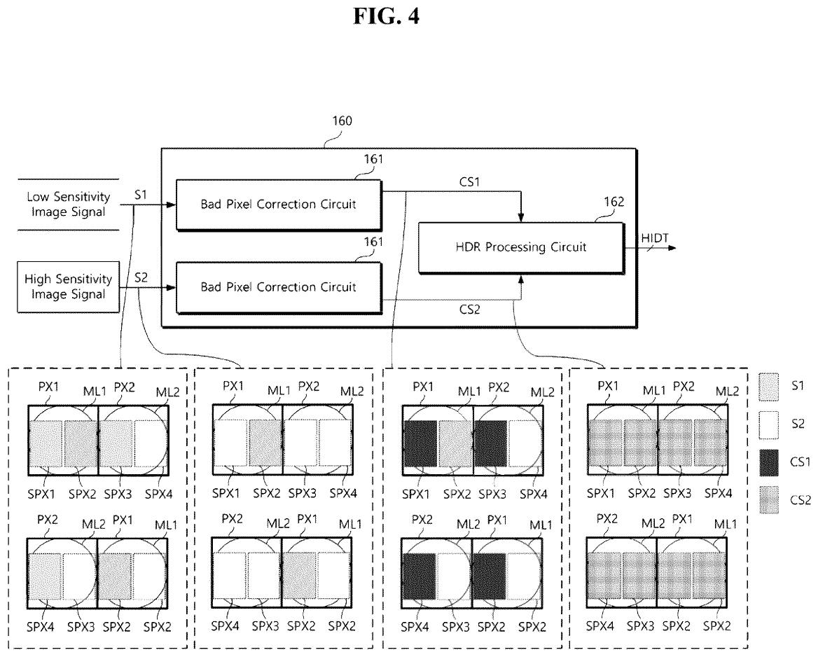

FIG. 4 is an example diagram illustrating a method of generating HDR image data HIDT based on the first pixel PX1 and the second pixel PX2 by the image signal processor 160 of FIG. 1. The method of generating HDR image data HIDT by the image signal processor 160 is described with reference to FIGS. 1 and 4. The image signal processor 160 may include a bad pixel correction circuit 161 and an HDR processing circuit 162.

The image signal processor 160 may receive a low-sensitivity image signal S1 and a high-sensitivity image signal S2 from the readout circuit 150 of FIG. 1.

For example, the low-sensitivity image signal S1 may include the first image signal IS1 and the second image signal IS2 of FIG. 2, based on a subset of sub-pixels of the first pixel PX1 and the second pixel PX2, excluding the second sub-pixel SPX2 of the first pixel PX1, during a first readout period.

For example, the low-sensitivity image signal S1 may include the first image signal IS1 and the second image signal IS2 based on a subset of sub-pixels corresponding to the same position with respect to the microlenses ML1 and ML2 in the first pixel PX1 and the second pixel PX2 during the first readout period.

For example, the high-sensitivity image signal S2 may include the third image signals IS3A and IS3B and the fourth image signal IS4 of FIG. 2, based on all sub-pixels of the first pixel PX1, excluding the second sub-pixel SPX2, and all sub-pixels of the second pixel PX2 during the second readout period.

Based on the image signals of pixels adjacent to the second sub-pixel SPX2, the bad pixel correction circuit 161 may perform bad pixel correction on the second sub-pixel SPX2 of the first pixel PX1 in the low-sensitivity image signal S1 and may respectively generate a corrected low-sensitivity image signal CS1 and a corrected high-sensitivity image signal CS2.

For example, the bad pixel correction circuit 161 may interpolate image signals of surrounding pixels having a color filter of the same color as the second sub-pixel SPX2 to generate the low-sensitivity image signal CS1 and the high-sensitivity image signal CS2 for the second sub-pixel SPX2. The bad pixel correction circuit 161 may generate the corrected low-sensitivity image signal CS1 and the corrected high-sensitivity image signal CS2 based on the low-sensitivity image signal CS1 and the high-sensitivity image signal CS2 of the second sub-pixel SPX2.

The HDR processing circuit 162 may generate HDR image data HIDT based on the corrected low-sensitivity image signal CS1 and the corrected high-sensitivity image signal CS2.

In the second mode, even when the second sub-pixel SPX2 of the first pixel PX1 does not output a pixel signal, the image sensor 100 of FIG. 1 may performing bad pixel correction on the image signal based on the second sub-pixel SPX2 to reliably generate HDR image data HIDT.

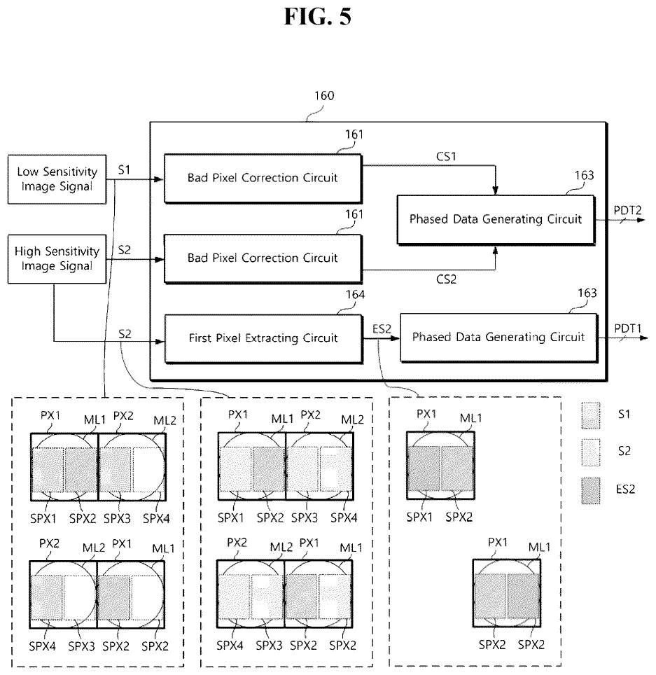

FIG. 5 is an example diagram illustrating a method of generating phase data PDT1 and PDT2 based on the first pixel and the second pixel in the second mode by the image signal processor 160 of FIG. 1. The method of generating phase data PDT1 and PDT2 by the image signal processor 160 is described with reference to FIGS. 1, 4, and 5. According one or more embodiments, the image signal processor 160 may output both the first phase data PDT1 and the second phase data PDT2, or may either the first phase data PDT1 or the second phase data PDT2.

The image signal processor 160 may include a bad pixel correction circuit 161, a phase data generation circuit 163, and a first pixel extracting circuit 164.

The image signal processor 160 may receive a low-sensitivity image signal S1 and a high-sensitivity image signal S2 from the readout circuit 150 of FIG. 1.

For example, the low-sensitivity image signal S1 and the high-sensitivity image signal S2 of FIG. 5 may be the low-sensitivity image signal S1 and the high-sensitivity image signal S2 described with reference to FIG. 4.

The bad pixel correction circuit 161 may generate a corrected low-sensitivity image signal CS1 and a corrected high-sensitivity image signal CS2 in the same manner as described with reference to FIG. 4.

The first pixel extracting circuit 164 may extract an image signal based on the first pixel PX1 of FIG. 1 from the high-sensitivity image signal S2 and output the extracted image signal as an extracted high-sensitivity image signal ES2. For example, information on the first pixel PX1 of FIG. 1 may be stored in an additional register. The first pixel extracting circuit 164 may extract the image signal based on the first pixel PX1 from the high-sensitivity image signal CS2 based on the information on the first pixel PX1.

The phase data generating circuit 163 may generate the first phase data PDT1 based on the extracted high-sensitivity image signal ES2.

For example, the phase data generating circuit 163 may extract an image signal disposed on one side with respect to a microlens from the high-sensitivity image signal S2 to generate a portion of the first phase data PDT1 and extract an image signal disposed on another side to generate another portion of the first phase data PDT1. For example, the phase data generating circuit 163 may extract image signals, disposed on the left and right sides with respect to the microlens, from the high-sensitivity image signal S2 to generate the first phase data PDT1.

The phase data generating circuit 163 may generate the second phase data PDT2 based on the corrected first image signal CIS1 and the corrected second image signal CIS2.

For example, the phase data generating circuit 163 may generate a portion of the second phase data PDT2 based on the corrected first image signal CIS1. The phase data generating circuit 163 may generate another portion of the second phase data PDT2 based on the portion of phase data generated from the first image signal CIS1 and the corrected second image signal CIS2. For example, an image signal obtained by subtracting the portion of phase data generated based on the first image signal CIS1 from the corrected second image signal CIS2 may be generated as another portion of the second phase data PDT2.

The first phase data PDT1 according to an embodiment may be generated based on an image signal based on the pixel signal of the first sub-pixel SPX1 of the first pixel PX1, and thus may be generated based on an unsaturated image signal. Accordingly, the first phase data PDT1 may be reliably generated in a wide dynamic range.

The second phase data PDT2 may be based on more pixels than the first phase data PDT1. Accordingly, the second phase data PDT2 may include phase information over a wider spatial range.

The image sensor 100 of FIG. 1 may output the first phase data PDT1 and the second phase data PDT2 having different characteristics, enabling an external device (for example, an application processor) to accurately perform autofocusing.

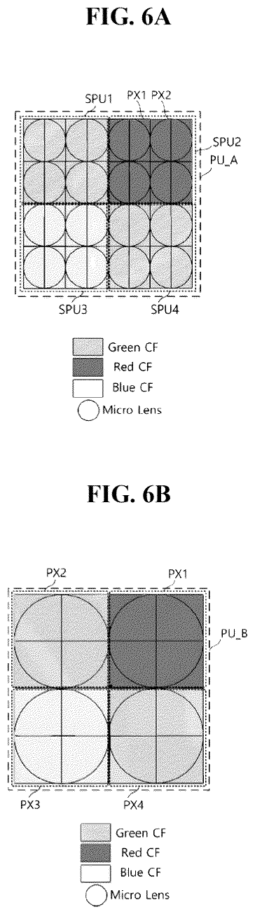

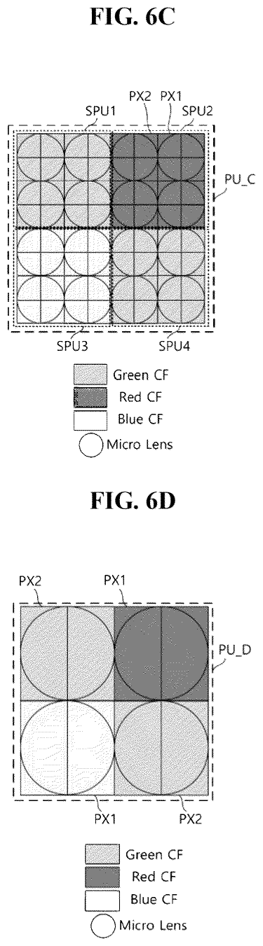

FIGS. 6A-6D are example diagrams illustrating pixels according to embodiments. Pixel units PU_A, PU_B, PU_C, and PU_D including the second pixel PX2 of FIG. 1 are illustrated in FIGS. 6A to 6D, and the pixel group PG of FIG. 1 may also include pixels that do not include the second pixel PX2. Pixels PX1 and PX2 of FIGS. 6A-6D may correspond to the first pixel PX1 and the second pixel PX2 of FIG. 1, respectively.

The pixel group PG of FIG. 1 may include one of the pixel units PU_A, PU_B, PU_C, and PU_D of FIGS. 6A-6D. The pixel group PG may include a plurality of pixel units.

A portion of the plurality of pixel units in each pixel group PG may include the first pixel PX1, and another portion may not include the first pixel PX1. Pixels of such pixel units may include the second pixel PX2.

The pixel units PU_A, PU_B, PU_C, and PU_D of FIGS. 6A to 6D may be examples of pixel units. When each pixel includes a plurality of sub-pixels sharing a microlens, the pixel units PU_A, PU_B, PU_C, and PU_D of FIGS. 6A to 6D may all be implemented as the pixel group PG of FIG. 1.

A pixel unit may correspond to a pattern of color filters. For example, the pixel group PG of FIG. 1 may include a plurality of pixel units, and each of the plurality of pixel units may have color filters of the same pattern.

In FIGS. 6A-6D, each of the pixel units PU_A, PU_B, PU_C, and PU_D is illustrated as a pixel unit based on color filters arranged in a Bayer pattern. However, the pixel group PG of FIG. 1 may include pixel units based on color filters arranged in other patterns.

In FIGS. 6A-6D, the first pixel PX1 is illustrated as a pixel with a red color filter. However, the first pixel PX1 may be independent of the color of the color filter.

Although a single pixel unit is illustrated in FIGS. 6A-6D, the number of pixel units including the first pixel PX1 may be even. In addition, the number of first pixels PX1, on which color filters of the same color are disposed, may be even.

For example, the image sensor 100 of FIG. 1 may further include another pixel unit, including a first pixel PX1 on which a red color filter may be disposed, in addition to the pixel unit PU_A of FIG. 6A. The image sensor 100 of FIG. 1 may further include an even number of other pixel units, including a first pixel PX1 on which a blue color filter is disposed, in addition to the pixel unit PU_A of FIG. 6A.

In the first pixels PX1 on which color filters of the same color are disposed, positions of the second sub-pixels SPX2 may be symmetrical with respect to the microlens.

Referring to FIG. 6A, the pixel unit PU_A may include a plurality of sub-pixel units SPU1, SPU2, SPU3, and SPU4 corresponding to color filters. Each of the sub-pixel units SPU1, SPU2, SPU3, and SPU4 may include four pixels. Each of the four pixels may include two sub-pixels sharing a microlens. One of the four pixels may be the first pixel PX1 of FIGS. 1-5.

Referring to FIG. 6B, the pixel unit PU_B may include a plurality of pixels PX1, PX2, PX3, and PX4 corresponding to color filters. The first pixel PX1, among the plurality of pixels PX1, PX2, PX3, and PX4 may correspond to the first pixel PX1 of FIG. 1. Each of the plurality of pixels PX1, PX2, PX3, and PX4 may include four sub-pixels sharing a microlens. At least one of the sub-pixels of the first pixel PX1 may correspond to the second sub-pixel SPX2 of FIG. 1.

Referring to FIG. 6C, the pixel unit PU_C may include a plurality of sub-pixel units SPU1, SPU2, SPU3, and SPU4 corresponding to color filters. Each of the sub-pixel units SPU1, SPU2, SPU3, and SPU4 may include four pixels. Each of the four pixels may include four sub-pixels sharing a microlens. One of the four pixels may be the first pixel PX1 of FIGS. 1 to 5. At least one of the sub-pixels of the first pixel PX1 may correspond to the second sub-pixel SPX2 of FIG. 1.

Referring to FIG. 6D, the pixel unit PU_D may include a plurality of pixels PX1, PX2, PX3, and PX4 corresponding to color filters. The first pixel PX1, among the plurality of pixels PX1, PX2, PX3, and PX4, may correspond to the first pixel PX1 of FIG. 1. Each of the plurality of pixels PX1, PX2, PX3, and PX4 may include two sub-pixels sharing a microlens. One of the sub-pixels of the first pixel PX1 may correspond to the second sub-pixel SPX2 of FIG. 1.

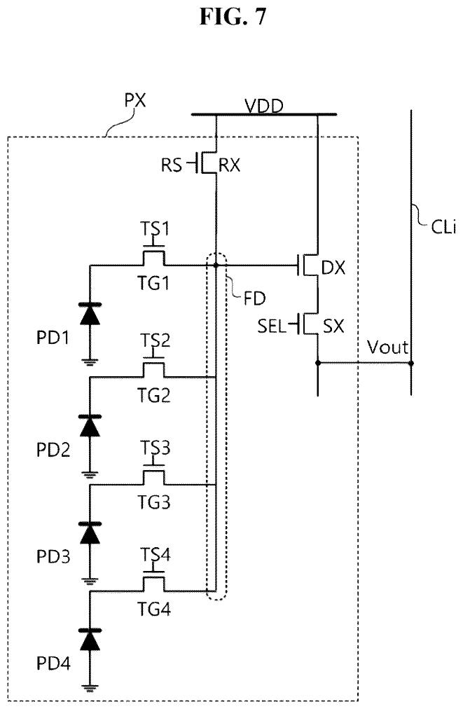

FIG. 7 is an example circuit diagram of a pixel PX according to an embodiment. FIG. 7 is an exemplary circuit diagram of the pixel PX, and pixels according to embodiments may have a circuit configuration different from that of FIG. 7. For example, a circuit of the pixel PX of FIG. 7 may correspond to the pixels PX1 and PX2 of the pixel unit PU_B in FIG. 6B. While FIGS. 7 to 39 are described based on the pixel unit PU_B of FIG. 6B, it will be apparent to those skilled in the art that similar structures may be applied to the pixel units PU_A, PU_C, and PU_D of FIGS. 6A, 6C, and 6D with appropriate modifications.

The pixel PX of the pixel unit PU_B may be described with reference to FIGS. 6B and 7.

The sub-pixels of the pixel PX may each include photoelectric elements PD1, PD2, PD3, and PD4 and transfer transistors TG1, TG2, TG3, and TG4 connecting the photoelectric elements PD1, PD2, PD3, and PD4 to a floating diffusion node FD. The transfer transistors TG1, TG2, TG3, and TG4 may be controlled by transfer control signals TS1, TS2, TS3, and TS4, respectively.

In a first mode, the transfer transistors TG1, TG2, TG3, and TG4 may be turned on at different times, and the photoelectric elements PD1, PD2, PD3, and PD4 may each transfer photocharges to the floating diffusion node FD.

In a second mode, the transfer transistors TG1, TG2, TG3, and TG4 of the first pixel PX1 and the second pixel PX2 may be controlled in different manners. For example, the first pixel PX1 and the second pixel PX2 disposed in the same row may be controlled in different manners. At a time point at which at least one transistor corresponding to the third sub-pixel SPX3 of the second pixel PX2 is turned on, at least one transistor corresponding to the second sub-pixel SPX2 of the first pixel PX1 may not be turned on. The at least one transistor corresponding to the second sub-pixel SPX2 may be maintained in an OFF state during a plurality of readout periods of the second mode.

The reset transistor RX may be turned on by a reset control signal RS, and the floating diffusion node FD may be reset by a power supply voltage VDD.

A voltage level at the floating diffusion node FD may be amplified through an operating driver DX, and may be output to a column line CLi through a select transistor SX. The select transistor SX may be controlled by a select signal SEL.

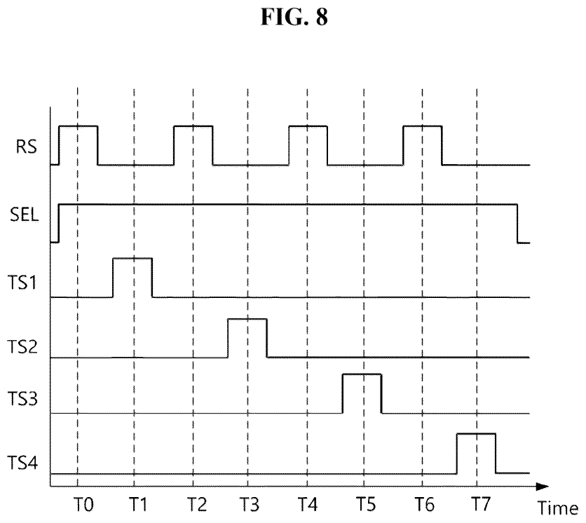

FIG. 8 is an example timing diagram illustrating the operation of the pixel PX in the first mode according to the embodiment of FIG. 7.

Referring to FIG. 8, the transfer transistors TG1, TG2, TG3, and TG4 may be turned on at different times by high-level transfer control signals TS1, TS2, TS3, and TS4, respectively. In addition, the photoelectric elements PD1, PD2, PD3, and PD4 may each transfer photocharges to the floating diffusion node FD. A pixel signal may be output based on the photocharges transferred to the floating diffusion node FD.

Before each of the photoelectric elements PD1, PD2, PD3, and PD4 transfers photocharges to the floating diffusion node FD, the floating diffusion node FD may be reset to the power supply voltage VDD of FIG. 7 by a high-level reset control signal RS. A reset pixel signal may be outputted based on the voltage level at the reset floating diffusion node FD. The readout circuit 150 of FIG. 1 may perform correlated double sampling (CDS) based on the pixel signal and the reset pixel signal.

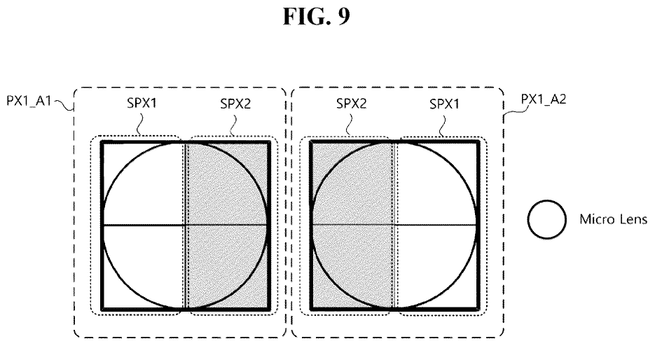

FIG. 9 is an example diagram illustrating a first pixel according to an embodiment. FIG. 9 illustrates an example of the first pixel according to the embodiment of FIG. 6B. The first pixels PX1_A1 and PX1_A2 of FIG. 9 may correspond to the first pixel PX1 of FIG. 1.

The first pixels PX1_A1 and PX1_A2 of FIG. 9 may be disposed in different pixel units, respectively. A color filter of the same color may be disposed in each of the first pixels PX1_A1 and PX1_A2.

FIG. 9 illustrates an example in which the second sub-pixel SPX2 of each of the first pixels PX1_A1 and PX1_A2 includes two sub-pixels.

Referring to FIG. 9, the second sub-pixel SPX2 of each of the first pixels PX1_A1 and PX1_A2 is disposed symmetrically with respect to a microlens. For example, with respect to the microlens, the second sub-pixel SPX2 of the first pixel PX1_A1 may be disposed on the right side and the second sub-pixel SPX2 of the first pixel PX1_A2 may be disposed on the left side.

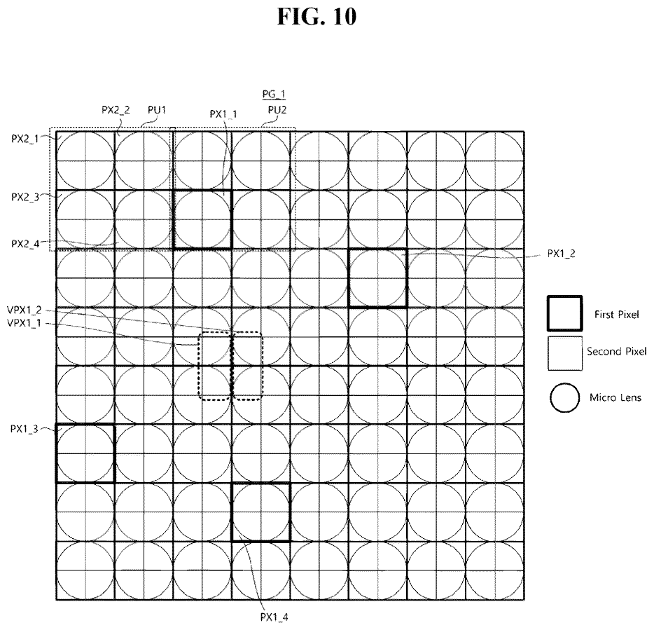

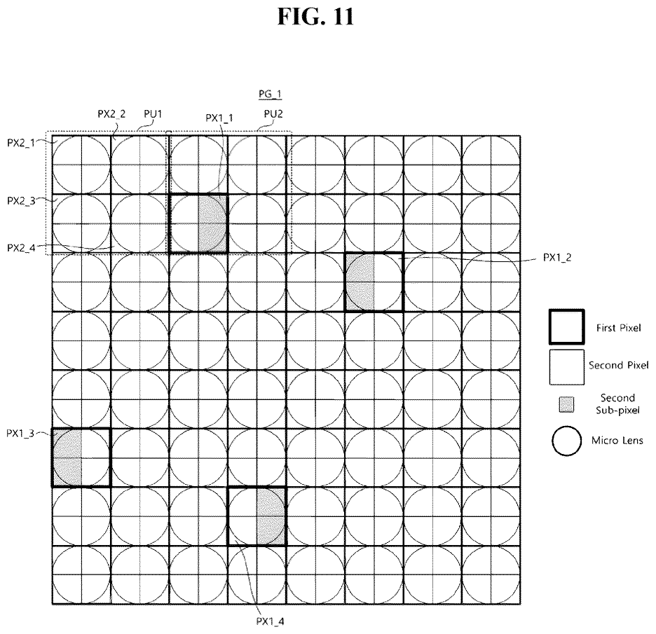

FIG. 10 is an example diagram illustrating a pixel group PG_1 including a first pixel according to an embodiment. The pixel group PG_1 may include the pixel unit PU_B according to the embodiment of FIG. 6B. The pixel array 110 of FIG. 1 may include a plurality of pixel groups PG_1 of FIGS. 10 and 11.

The pixel group PG_1 may include a plurality of pixel units. FIG. 10 illustrates an example in which the pixel group PG_1 includes 16 pixel units. Color filters of the same pattern may be disposed in each of the pixel units.

A portion of the pixel units may include a first pixel, and another portion of the pixel units may not include the first pixel. FIG. 10 illustrates an example in which each of four pixel units, among the plurality of pixel units, includes one of the first pixels PX1_1, PX1_2, PX1_3, and PX1_4. For example, the first pixel unit PU1 may include only second pixels PX2_1, PX2_2, PX2_3, and PX2_4, and the second pixel unit PU2 may include one first pixel PX1_1 and three second pixels.

FIG. 10 illustrates an example in which the pixel group PG_1 includes four first pixels PX1_1, PX1_2, PX1_3, and PX1_4, but the pixel group PG_1 may include fewer or more than four first pixels.

Referring to FIG. 10, the first pixels PX1_1, PX1_2, PX1_3, and PX1_4 may be disposed in different rows of the pixel group PG_1. The first pixels PX1_1, PX1_2, PX1_3, and PX1_4 may be disposed in different columns of the pixel group PG_1.

In one or more embodiments, the number of first pixels corresponding to color filters of the same color may be even. For example, a color filter of a first color may be disposed in the first pixels PX1_1 and PX1_3, and a color filter of a second color may be disposed in the first pixels PX1_2 and PX1_4.

In one or more embodiments, a first intermediate position of a second sub-pixel disposed at a first position with respect to the microlens may be adjacent to a second intermediate position of a second sub-pixel disposed at a second position. The first pixels may be disposed considering the intermediate positions of the second sub-pixels.

For example, referring to FIG. 10, the second sub-pixels of the first pixels PX1_1 and PX1_4 may be disposed at a first position with respect to the microlens, and the second sub-pixels of the first pixels PX1_2 and PX1_3 may be disposed at a second position with respect to the microlens. The pixels VPX1_1 at the first intermediate position of the first pixels PX1_1 and PX1_4 may be adjacent to the pixels VPX1_2 at the second intermediate position of the first pixels PX1_2 and PX1_3. Accordingly, the first phase data PDT1 of FIG. 5 may generate phase data based on a plurality of pieces of partial phase data from adjacent positions, and the external device may accurately perform autofocusing.

FIG. 11 is a diagram illustrating an example of arrangement of first pixels in a pixel group PG_1 including a first pixel according to an embodiment.

The pixel group PG_1 of FIG. 11 has the same form as the pixel group PG_1 of FIG. 10, and redundant descriptions are omitted.

Referring to FIG. 11, the pixel group PG_1 may include four first pixels PX1_1, PX1_2, PX1_3, and PX1_4, and the second sub-pixel of each of the first pixels PX1_1, PX1_2, PX1_3, and PX1_4 may include two sub-pixels.

In one or more embodiments, the positions of the second sub-pixels of the first pixels PX1_1, PX1_2, PX1_3, and PX1_4 may be symmetric with respect to the microlens.

For example, referring to FIG. 10, the second sub-pixels of the first pixels PX1_1 and PX1_4 may be disposed at a first position with respect to the microlens, and the second sub-pixels of the first pixels PX1_2 and PX1_3 may be disposed at a second position with respect to the microlens. With respect to the microlens, the first position and the second position may be symmetric to the left and right sides.

Accordingly, the first phase data PDT1 of FIG. 6 may generate phase data based on a plurality of pieces of partial phase data having opposite phases, and the external device may accurately perform autofocusing.

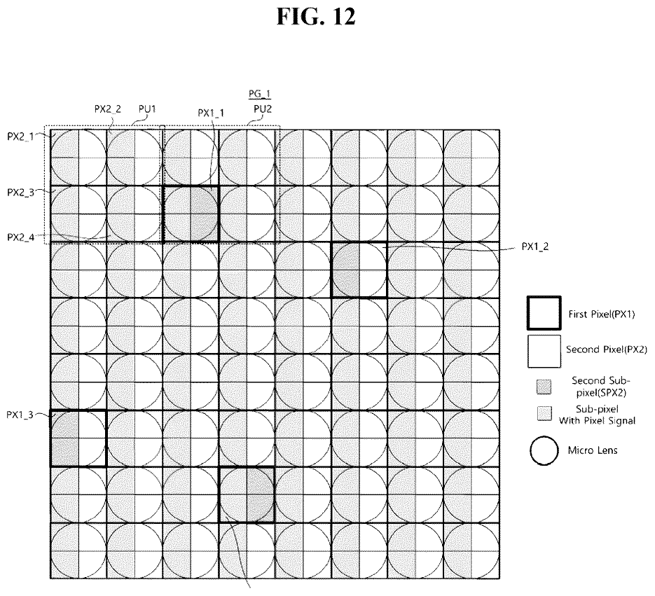

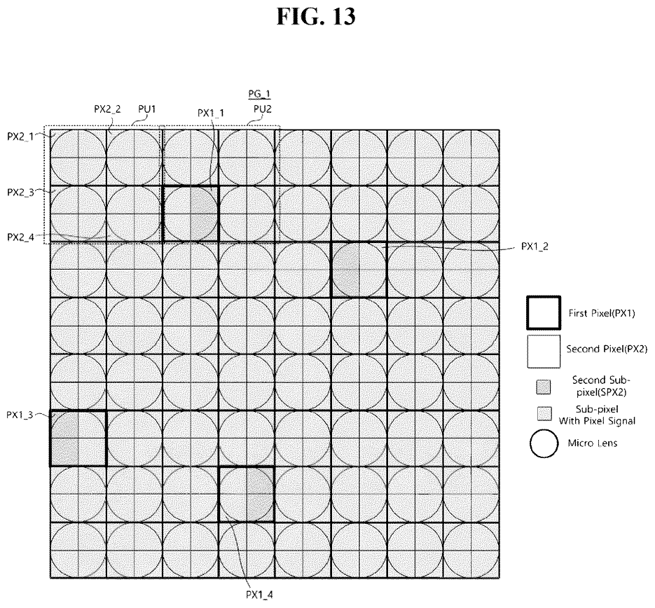

FIGS. 12 and 13 are example diagrams illustrating a first readout operation and a second readout operation, respectively, in a second mode, of a pixel group PG_1 including first pixels PX1_A1 and PX1_A2, according to the embodiment of FIG. 9. Descriptions redundant to those of FIGS. 10 and 11 are omitted.

Referring to FIG. 12, in the first readout operation, at least one first pixel PX1 and second pixel PX2 may each output a pixel signal based on at least one sub-pixel, while at least one first pixel PX1 may not output a pixel signal. The second sub-pixel SPX2 may not output a pixel signal.

For example, FIG. 12 illustrates that, in the first readout operation, each pixel outputs a pixel signal based on sub-pixels disposed on the left side with respect to the microlens.

For example, the second pixels PX2_1, PX2_2, PX2_3, and PX2_4 may output pixel signals based on sub-pixels disposed on the left side with respect to the microlens.

However, pixels PX1_2 and PX1_3 including a second sub-pixel SPX2 disposed on the left side with respect to the microlens may not output a pixel signal, while pixels PX1_1 and PX1_4 including a second sub-pixel SPX2 disposed on the right side with respect to the microlens may output a pixel signal.

Referring to FIG. 13, in the second readout operation, all pixels PX1 and PX2 may each output a pixel signal based on at least one sub-pixel. The second sub-pixel SPX2 may not output a pixel signal. The pixel signals output in the second readout operation may not be based on the second sub-pixel SPX2.

For example, the second pixels PX2_1, PX2_2, PX2_3, and PX2_4 may output pixel signals based on all sub-pixels. However, the first pixels PX1_1, PX1_2, PX1_3, and PX1_4 may output pixel signals based on sub-pixels other than the second sub-pixel SPX2.

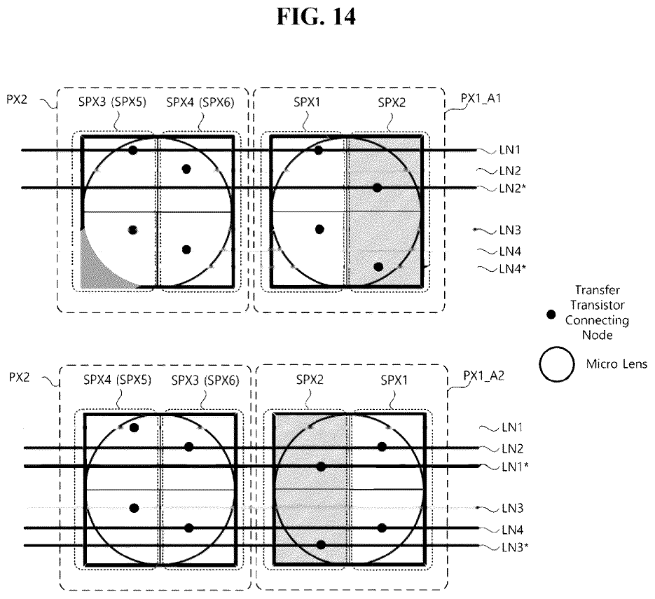

FIG. 14 is an example diagram illustrating an example of interconnections for controlling the first pixels PX1_A1 and PX1_A2 according to the embodiment of FIG. 9.

The first pixels PX1_A1 and PX1_A2 and the second pixel PX2 may be disposed in the same row. The first pixels PX1_A1 and PX1_A2 may include a first sub-pixel SPX1 and a second sub-pixel SPX2. The second pixel PX2 may include a third sub-pixel SPX3 at a position corresponding to the first sub-pixel SPX1 and a fourth sub-pixel SPX4 at a position corresponding to the second sub-pixel SPX2. In the one or more embodiments, in the second mode, sub-pixels that output pixel signals during the first readout period may be referred to as fifth sub-pixels SPX5, whereas sub-pixels that do not output pixel signals may be referred to as sixth sub-pixels SPX6.

In one or more embodiments, the second sub-pixel SPX2 of the first pixels PX1_A1 and PX1_A2 and the fourth sub-pixel SPX4 of the second pixel PX2 may receive transfer control signals through different interconnections.

For example, referring to FIG. 14, the second sub-pixel SPX2 of the first pixel PX1_A1 may receive a transfer control signal through signal interconnections LN2* and LN4* among signal interconnections LN1, LN2, LN2*, LN3, LN4, and LN4*. The fourth sub-pixel SPX4 of the second pixel PX2 disposed in the same row as the first pixel PX1_A1 may receive a transfer control signal through interconnections LN2 and LN4. Similarly, the second sub-pixel SPX2 of the first pixel PX1_A2 may receive a transfer control signal through signal interconnections LN1* and LN3* among signal interconnections LN1, LN2, LN1*, LN3, LN4, and LN3*, and the fourth sub-pixel SPX4 of the second pixel PX2 disposed in the same row may receive a transfer control signal through the signal interconnections LN1 and LN3.

In one or more embodiments, the first sub-pixel SPX1 of the first pixels PX1_A1 and PX1_A2 may receive a transfer control signal through the same interconnection as or an interconnection different from that of the third sub-pixel SPX3 of the second pixel PX2. FIG. 14 illustrates an example in which the first sub-pixel SPX1 of the first pixels PX1_A1 and PX1_A2 receives a transfer control signal through the same interconnection as the third sub-pixel SPX3 of the second pixel PX2. The first sub-pixel SPX1 of the first pixel PX1_A1 may receive a transfer control signal through the same interconnections LN1 and LN3 as the third sub-pixel SPX3 of the first pixel PX1, and the first sub-pixel SPX1 of the first pixel PX1_A2 may receive a transfer control signal through the same interconnections LN2 and LN4 as the third sub-pixel SPX3 of the first pixel PX1.

Accordingly, the second sub-pixel SPX2 of the first pixels PX1_A1 and PX1_A2 may be controlled through interconnections, separate from those of the second pixel PX2 disposed in the same row, to be controlled independently of other sub-pixels during the first and second readout periods in the second mode.

For example, during the first readout period, while pixel signals are output by the fifth sub-pixels SPX5 of the second pixel PX2, the second sub-pixel SPX2 of the first pixel PX1_A2 may not output a pixel signal due to a transfer control signal transmitted through the wirings LN1* and LN3*.

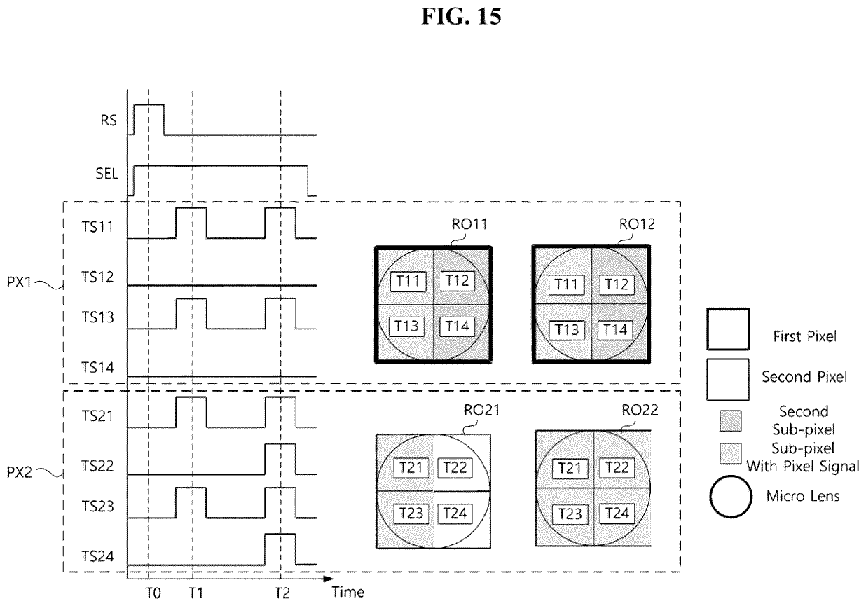

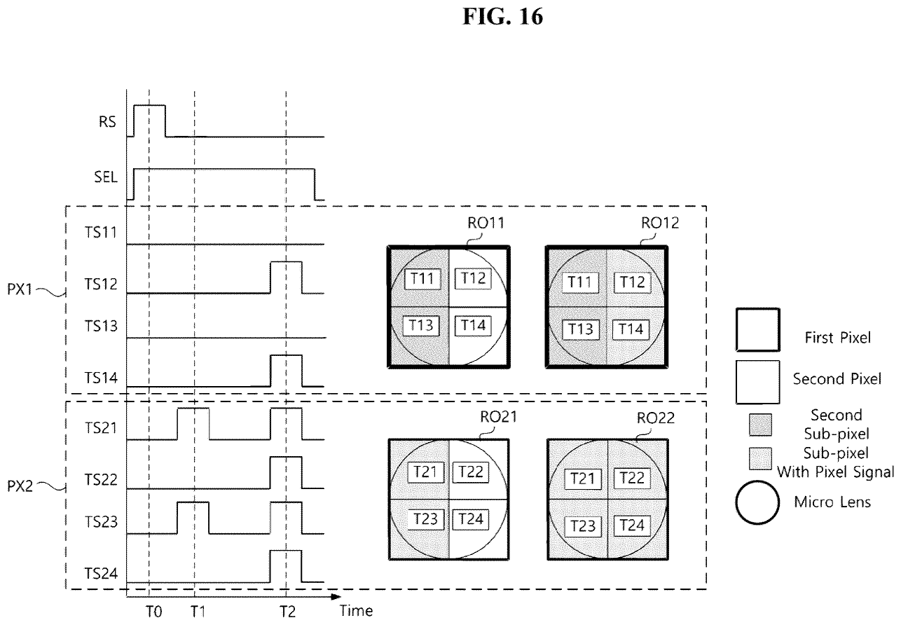

FIG. 15 is an example diagram illustrating first readout operations RO11 and RO21 and second readout operations RO12 and RO22 of a first pixel PX1_A1 according to the embodiment of FIG. 9, and FIG. 16 is a diagram illustrating first readout operations RO11 and RO21 and second readout operations RO12 and RO22 of a first pixel PX1_A2. The first pixel PX1 of FIG. 15 may correspond to the first pixels PX1_A1 and PX1_A2 of FIG. 9. The second pixel PX2 may be disposed in the same row as the first pixels PX1_A1 and PX1_A2. The transfer control signals TS11, TS12, TS13, TS14, TS21, TS22, TS23, and TS24 may control transistors T11, T12, T13, T14, T21, T22, T23, and T24, respectively.

Referring to FIG. 15, the first pixel PX1_A1 and the second pixel PX2 may output a pixel signal having a reset level at time TO in response to a reset control signal RS. The first pixel PX1_A1 and the second pixel PX2 may perform a first readout operation at time T1, and may perform a second readout operation at time T2.

At time T1, a subset of sub-pixels of the first pixel PX1_A1 may output a pixel signal by high-level transfer control signals TS11 and TS13, and a subset of sub-pixels of the second pixel PX2 may output a pixel signal by high-level transfer control signals TS21 and TS23.

At time T2, all sub-pixels of the first pixel PX1_A1, excluding the second sub-pixel SPX2, may output a pixel signal by high-level transfer control signals TS11 and TS13, and all sub-pixels of the second pixel PX2 may output a pixel signal by high-level transfer control signals TS21, TS22, TS23, and TS24.

Referring to FIG. 16, at time T1, the first pixel PX1_A1 may not output a pixel signal. The remaining operations are the same as those in FIG. 15. As described with reference to FIG. 14, the second sub-pixel SPX2 of the first pixel PX1 may receive a transfer control signal through separate interconnections, and thus may be controlled differently from the second pixel PX2.

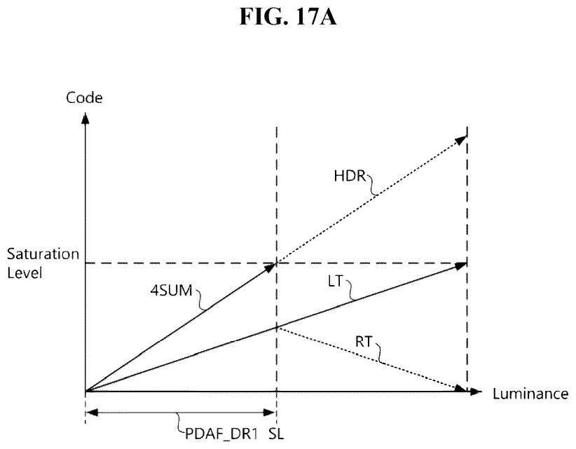

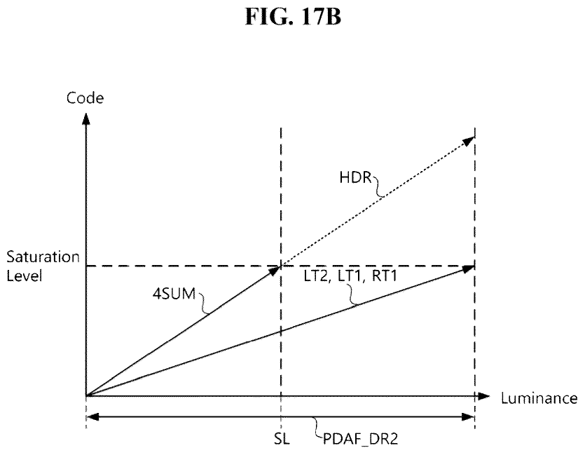

FIG. 17A is a diagram illustrating phase data of an image sensor according to an example, and FIG. 17B is a diagram illustrating phase data of an image sensor including the first pixels PX1_A1 and PX1_A2 according to the embodiment of FIG. 9.

Referring to FIG. 17A, in a second mode, all pixels of an image sensor according to an example may generate a first image signal LIS based on a subset of sub-pixels during a first readout operation and output a second image signal 4SUM based on all sub-pixels during the second readout operation. For example, the first image signal LIS of the image sensor according to the example may be based on sub-pixels disposed on the left or right side with respect to a microlens.

The image sensor according to the example may generate a third image signal RIS by subtracting the first image signal LIS from the second image signal 4SUM to generate phase data. HDR image data may be generated based on the second image signal 4SUM and the first image signal LIS.

The second image signal 4SUM of the image sensor according to the example may be a high-sensitivity image signal based on the pixel signals of all sub-pixels, and thus may reach a saturation level at relatively low brightness. Even at brightness higher than the brightness SL corresponding to the saturation level, a previously saturated second image signal 4SUM may have a code value corresponding to the saturation level, while the code value of the first image signal LIS, which is a low-sensitivity image signal, may continue to increase. Accordingly, the code value of the third image signal RIS may increase up to the brightness SL but decrease at brightness higher than the brightness SL. As a result, phase data according to the example is generated based on the first image signal LIS and the third image signal RIS, so that autofocusing may be inaccurately performed. An electronic device using phase data according to the example may perform accurate autofocusing only in a narrow dynamic range PDAF_DR1.

Referring to FIG. 17B, the first phase data PDT1 described with reference to FIGS. 1-9 may be generated based on image signals LIS1 and RIS1 based on a subset of sub-pixels of the first pixels PX1_A1 and PX1_A2 during the second readout operation. For example, the image signals LIS1 and RIS1 may be based on the first sub-pixel SPX1 of FIG. 9 disposed on the left or right side with respect to the microlens of the first pixels PX1_A1 and PX1_A2.

The first phase data PDT1 may be generated based on image signals LIS1 and RIS1 based on a subset of sub-pixels of the first pixels PX1_A1, PX1_A2, and thus may not be saturated even at the brightness SL. Accordingly, an electronic device using the first phase data PDT1 may perform accurate autofocusing in a wide dynamic range PDAF_DR2.

HDR image data may be generated based on a first image signal LIS2 based on a subset of sub-pixels of the second pixel (for example, PX2 of FIG. 10) and a second image signal 4SUM based on all sub-pixels. For example, a low-illuminance range of the HDR image data may be generated based on the second image signal 4SUM, and a high-illuminance range of the HDR image data may be generated based on an image signal obtained by amplifying the first image signal LIS2 by a factor of two. As described in FIG. 4, a bad-pixel-corrected image signal for the sub-pixels of the first pixel may also be used to generate the HDR image data.

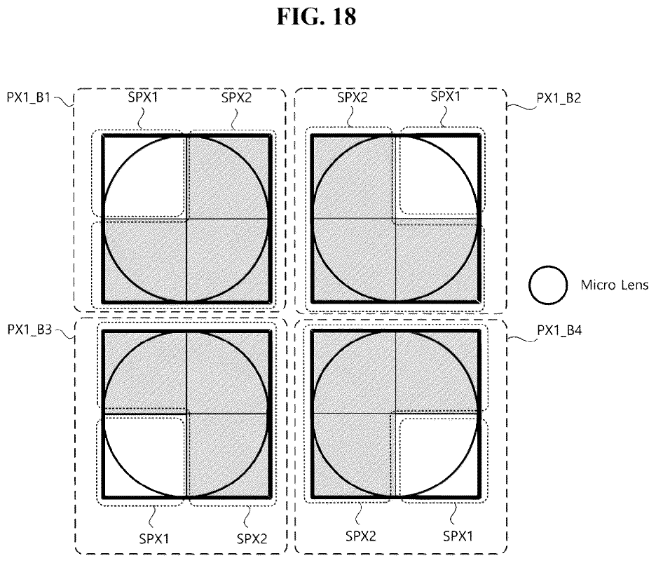

FIG. 18 is an example diagram illustrating a first pixel according to an embodiment. FIG. 18 illustrates an example of the first pixel according to the embodiment of FIG. 6B. The first pixels PX1_B1, PX1_B2, PX1_B3, and PX1_B4 of FIG. 18 may correspond to the first pixel PX1 of FIG. 1.

Referring to FIG. 18, each of the first pixels PX1_B1, PX1_B2, PX1_B3, and PX1_B4 may include one first sub-pixel SPX1 and three second sub-pixels SPX2. With respect to the microlens, positions of the first sub-pixels SPX1 included in the first pixels PX1_B1, PX1_B2, PX1_B3, and PX1_B4 may be different from each other. With respect to the microlens, the positions of the second sub-pixels SPX2 included in the first pixels PX1_B1, PX1_B2, PX1_B3, and PX1_B4 may be different from each other. For example, the first sub-pixel SPX1 of each of the first pixels PX1_B1, PX1_B2, PX1_B3, and PX1_B4 may be disposed at one of the top-left, top-right, bottom-left, or bottom-right with respect to the microlens. A direction with respect to the microlens may be a direction in which the pixel array may be viewed perpendicularly to a substrate.

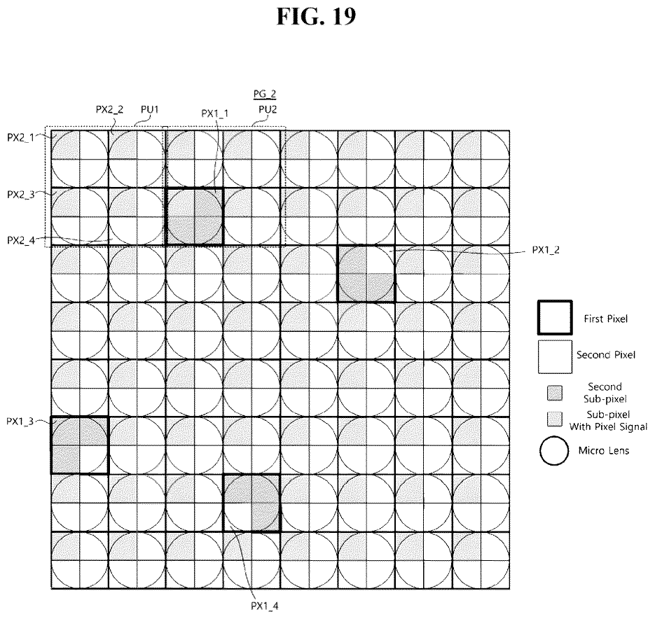

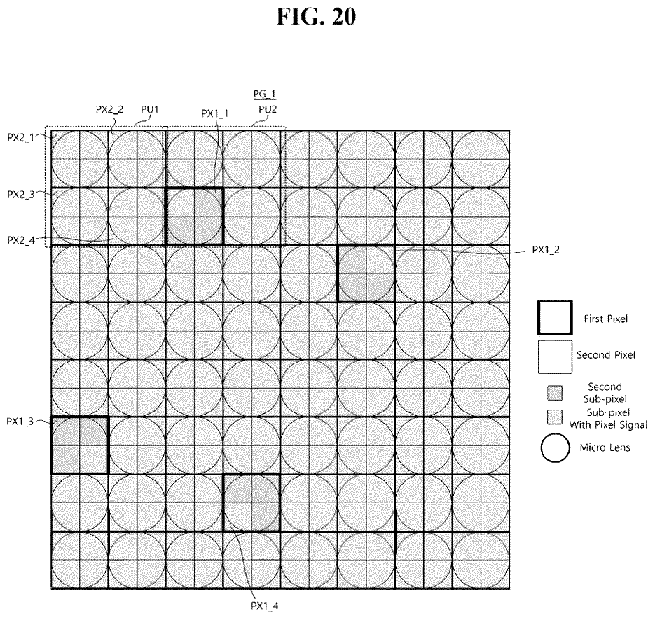

FIGS. 19 and 20 are example diagrams, respectively illustrating a first readout operation and a second readout operation in a second mode of a pixel group PG_2 including the first pixels PX1_1, PX1_2, PX1_3, and PX1_4 according to the embodiment of FIG. 18. The first pixels PX1_1, PX1_2, PX1_3, and PX1_4 may correspond to the first pixels PX1_B1, PX1_B2, PX1_B4, and PX1_B3 of FIG. 18, respectively. Descriptions redundant to those of FIGS. 12 and 13 are omitted.

Referring to FIG. 19, in the first readout operation, at least one first pixel PX1_1 and second pixel PX2 may each output a pixel signal based on at least one sub-pixel, while at least one first pixel PX1_2, PX1_3, and PX1_4 may not output a pixel signal. The second sub-pixel SPX2 may not output a pixel signal.

For example, each of the second pixels PX2 may output a pixel signal based on sub-pixels disposed at the top-left with respect to the microlens in the first readout operation. The first pixels PX1_1, PX1_B2, PX1_B3, and PX1_B4 may output a pixel signal based on sub-pixels disposed at the top-left when the second sub-pixel SPX2 is not disposed at the top-left with respect to the microlens.

Referring to FIG. 20, all pixels may each output a pixel signal based on at least one sub-pixel in the second readout operation. The second sub-pixel SPX2 may not output a pixel signal. The pixel signals output in the second readout operation may not be based on the second sub-pixel SPX2.

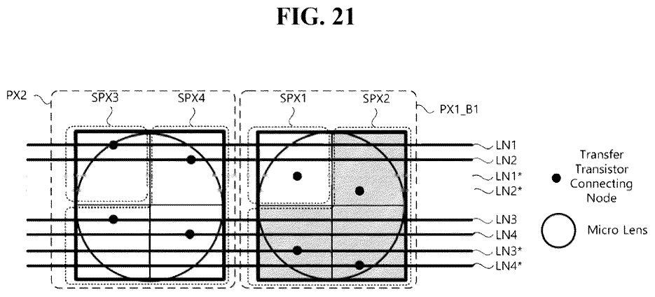

FIGS. 21 to 28 are example diagrams illustrating examples of interconnections for controlling the first pixels PX1_B1, PX1_B2, PX1_B3, and PX1_B4 according to the embodiment of FIG. 18, as well as a first readout operation RO11 and a second readout operation RO12 of the first pixels PX1_B1, PX1_B2, PX1_B3, and PX1_B4. Descriptions similar or redundant to those of FIGS. 14 to 16 are omitted, and the examples are described focusing on differences from FIGS. 14 to 16.

Referring to FIG. 21, all sub-pixels of the first pixel PX1_B1 may receive transfer control signals through interconnections, separate from those of the sub-pixels of the second pixel PX2. For example, the first pixel PX1_B1 may receive transfer control signals through interconnections LN1*, LN2*, LN3*, and LN4*, and the second pixel PX2 may receive transfer control signals through interconnections LN1, LN2, LN3, and LN4.

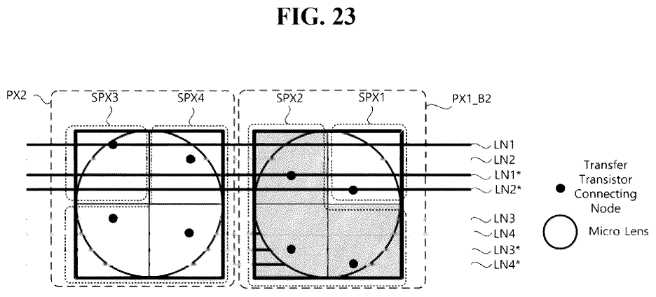

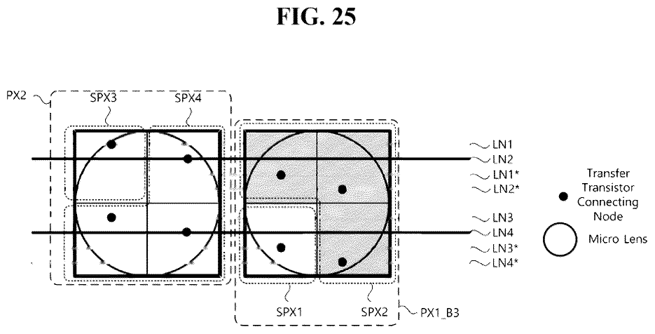

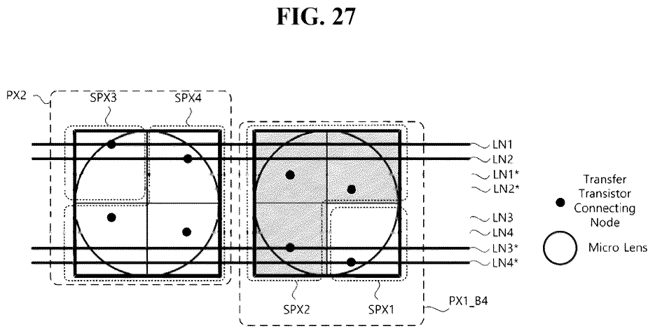

Similarly, the first pixel PX1_B2 of FIG. 23, the first pixel PX1_B3 of FIG. 25, and the first pixel PX1_B4 of FIG. 27 may also have all their sub-pixels receive transfer control signals through interconnections, separate from those of the sub-pixels of the second pixel PX2.

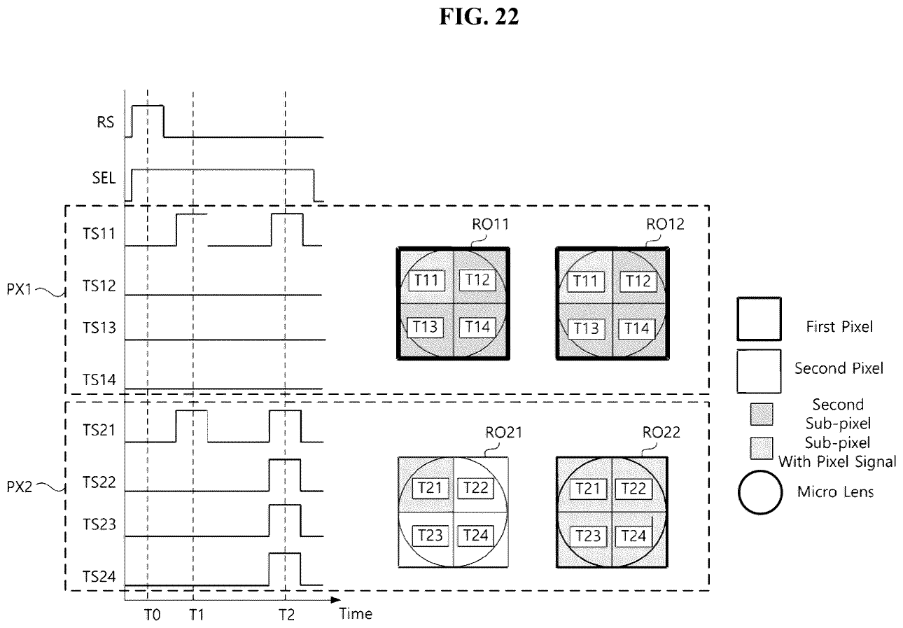

Referring to FIG. 22, in the first readout operations RO11 and RO21, a pixel signal based on a sub-pixel disposed at the top-left with respect to a microlens of the first pixel PX1_B1 and the second pixel PX2 may be output. The sub-pixel at the top-left of the first pixel PX1_B1 may not be a second sub-pixel SPX2, so that a pixel signal may be output at time T1 based on a transfer control signal TS11. The second sub-pixels SPX2 of the first pixel PX1_B1 may not output a pixel signal in both the first readout operation RO11 and the second readout operation RO12 due to the transfer control signals TS12, TS13, and TS14.

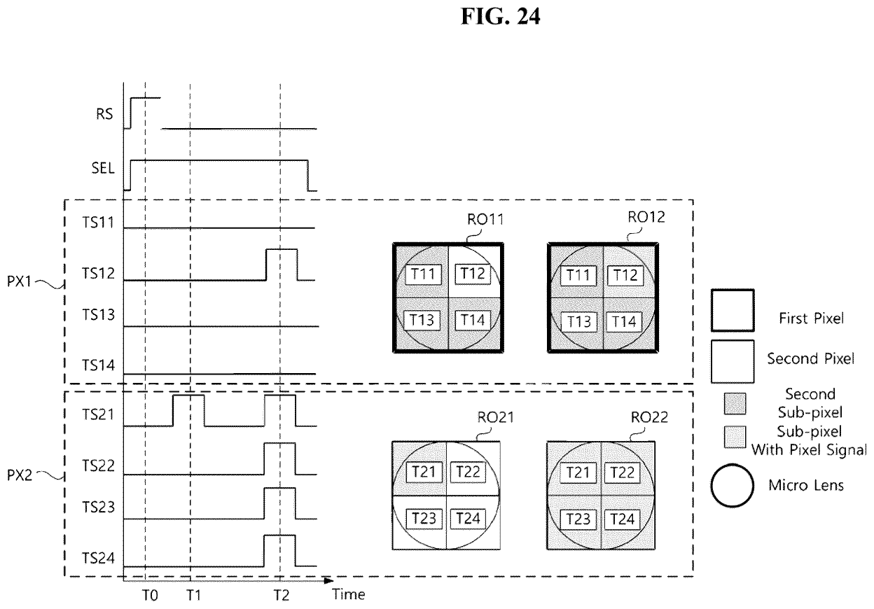

Referring to FIG. 24, in the first readout operation RO21, a pixel signal based on the sub-pixel disposed at the top-left with respect to the microlens of the second pixel PX2 may be output. The sub-pixel at the top-left of the first pixel PX1_B2 may be the second sub-pixel SPX2, so that a pixel signal may not be output at time T1 based on the transfer control signal TS11. The second sub-pixels SPX2 of the first pixel PX1_B2 may not output a pixel signal in both the first readout operation RO11 and the second readout operation RO12 due to the transfer control signals TS11, TS13, and TS14. In the second readout operation RO12, only the sub-pixel connected to the transfer transistor T12 of the first pixel PX1_B2 may output a pixel signal by the transfer control signal TS12.

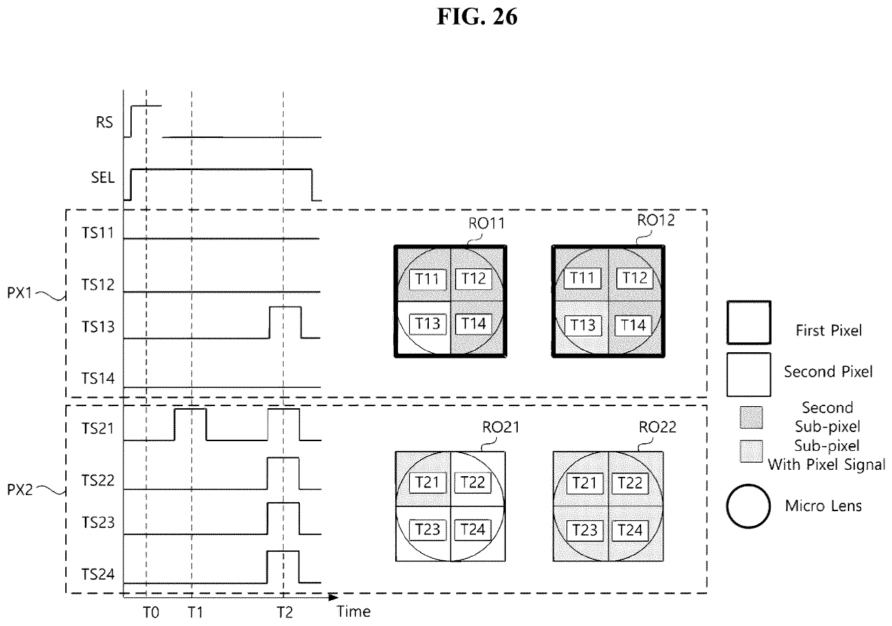

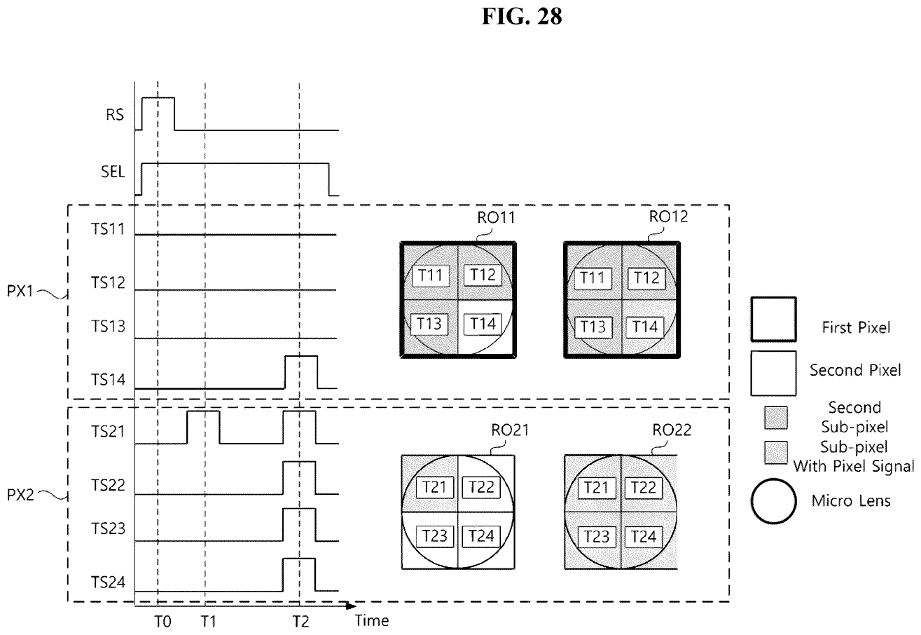

Referring to FIGS. 26 and 28, the first pixels PX1_B3 and PX1_B4 may not output a pixel signal in the first readout operation RO11 and may each output a pixel signal based on one first sub-pixel in the second readout operation RO12.

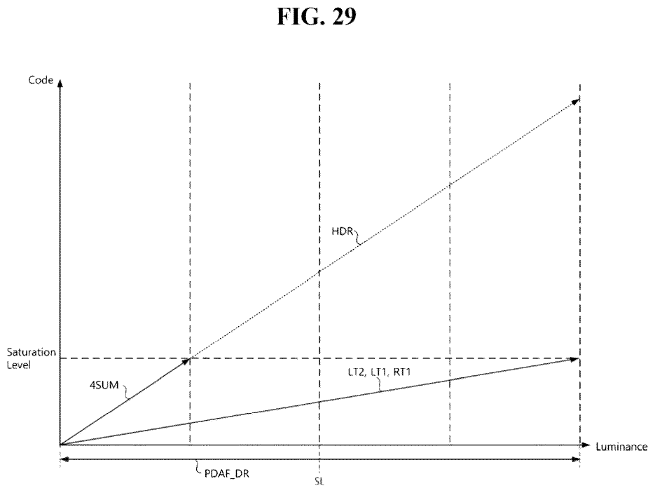

Referring to FIG. 29, the first phase data PDT1 described with reference to FIGS. 1 to 9 may be generated based on image signals LT1 and RT1 based on the first sub-pixels output during the second readout operation RO12 of the first pixels PX1_B1, PX1_B2, PX1_B3, and PX1_B4 described with reference to FIGS. 21 to 28.

For example, during the second readout operation RO12, a portion of the phase data of the first phase data PDT1 may be generated based on image signals LIS based on the first pixel PX1_B1 of FIG. 22 and the first pixel PX1_B3 of FIG. 26. Another portion of the phase data of the first phase data PDT1 may be generated based on image signals RIS based on the first pixel PX1_B2 of FIG. 24 and the first pixel PX1_B4 of FIG. 28.

The first phase data PDT1 may be generated based on image signals LIS and RIS based on a subset of sub-pixels of the first pixel PX1, and thus may not be saturated even at the brightness SL. Accordingly, an electronic device using the first phase data PDT1 may perform accurate autofocusing in a wide dynamic range PDAF_DR2.

HDR image data may be generated based on a first image signal LT based on a subset of sub-pixels of the second pixel PX2 and a second image signal 4SUM based on all sub-pixels. For example, a low-illuminance range of the HDR image data may be generated based on a second image signal 4SUM, and a high-illuminance range of the HDR image data may be generated based on an image signal obtained by amplifying the first image signal LT by a factor of four. As described in FIG. 4, a bad-pixel-corrected image signal for the sub-pixels of the first pixel may be used to generate the HDR image data.

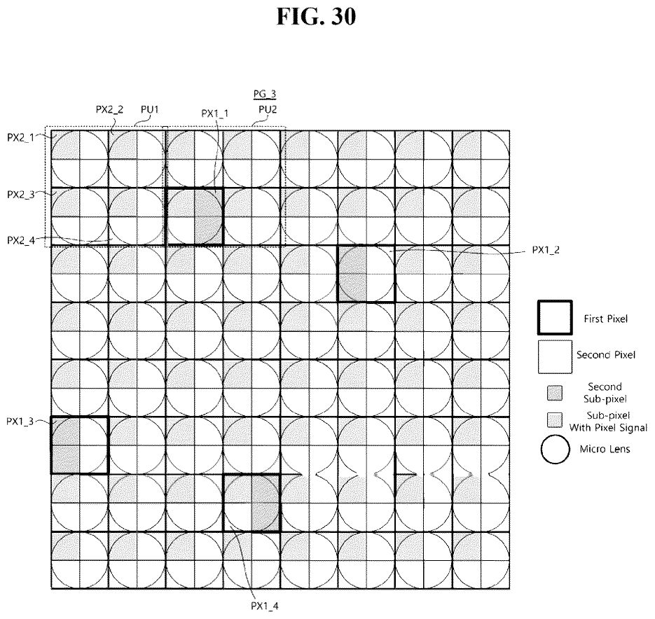

FIG. 30 is an example diagram illustrating the first readout operation in the second mode of a pixel group PG_3 including the first pixels PX1_A1 and PX1_A2 according to the embodiment of FIG. 9. The first readout operation in the second mode of the pixel group PG_3 may be the same as that in FIG. 13. Descriptions redundant to those of FIGS. 12, 13, and 21-28 are omitted. Each of the first pixels PX1_1, PX1_2, PX1_3, and PX1_4 of FIG. 30 may correspond to one of the first pixels PX1_A1 and PX1_A2 of FIG. 9.

FIG. 30, in contrast to FIG. 12, illustrates that in the first readout operation, the first pixels PX1_1, PX1_2, PX1_3, and PX1_4 and the second pixel PX2 may output a pixel signal based on a sub-pixel disposed at the top-left with respect to the microlens. When the sub-pixel at the top-left of the first pixels PX1_1, PX1_2, PX1_3, and PX1_4 is a second sub-pixel SPX2, the first pixels PX1_1, PX1_2, PX1_3, and PX1_4 may not output a pixel signal in the first readout operation. For example, in the first readout operation, the first pixels PX1_1 and PX1_4 may output a pixel signal, while the first pixels PX1_2 and PX1_3 may not output a pixel signal.

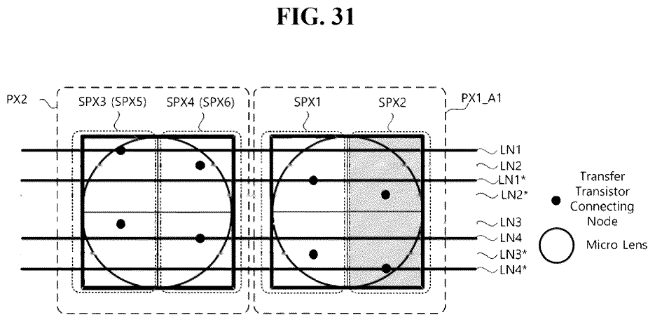

FIGS. 31 to 34 are example diagrams illustrating examples of interconnections for controlling the first pixels PX1_A1 and PX1_A2 according to the embodiment of FIG. 9, as well as readout operations RO11 and RO12 of the first pixels PX1_A1 and PX1_A2. Descriptions similar or redundant to those of FIGS. 14 to 16 and 21 to 28 are omitted, and the embodiments are described focusing on differences from FIGS. 14 to 16 and 21 to 28.

In the examples described with reference to FIGS. 31 to 34, HDR image data with four times the sensitivity improvement may be generated, unlike the HDR image data with twice the sensitivity improvement in the examples of FIGS. 12 to 14. For example, 12-bit HDR image data may be generated based on a 10-bit pixel signal.

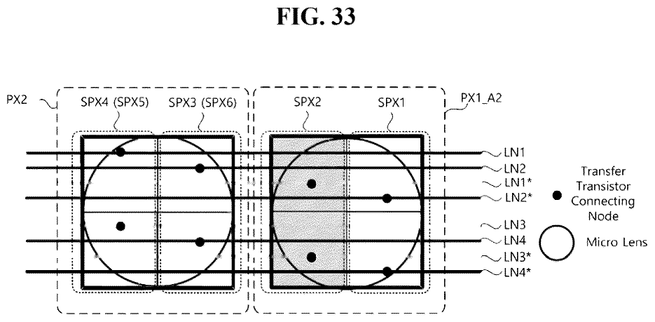

Referring to FIGS. 31 and 33, all sub-pixels of the first pixels PX1_A1 and PX1_A2 may receive transfer control signals through interconnections, separate from those of the sub-pixels of the second pixel PX2.

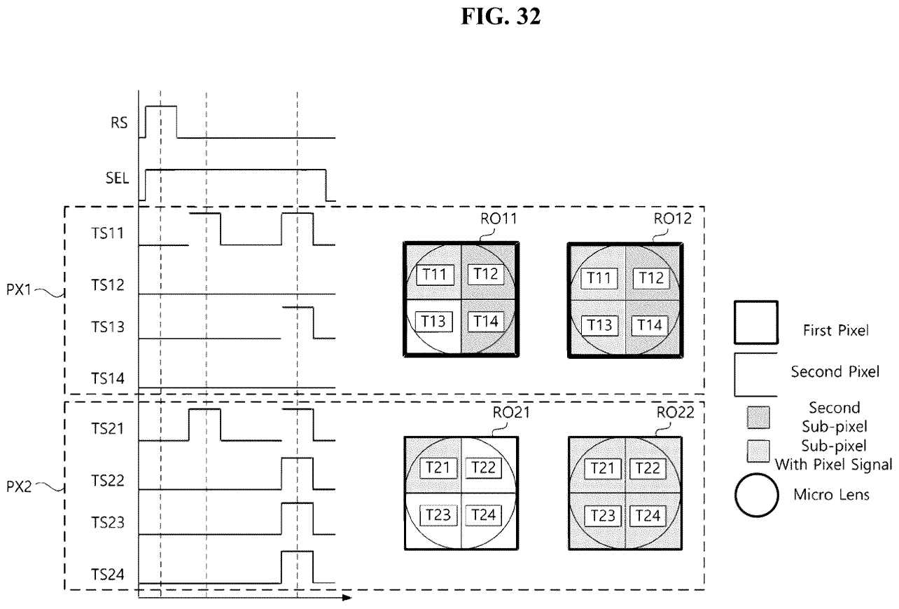

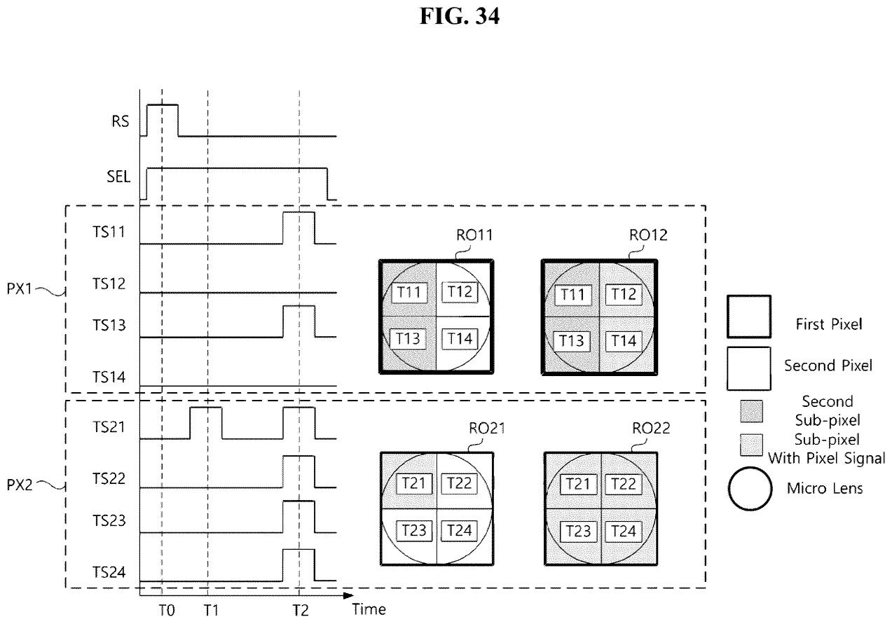

Referring to FIG. 32, in the first readout operation RO11, the first pixel PX1 may output a pixel signal based on the sub-pixel disposed at the top-left with respect to the microlens. The first pixel PX1 of FIG. 32 may correspond to the first pixel PX1_A1 of FIG. 31. Referring to FIG. 34, in the first readout operation RO11, the first pixel PX1 may not output a pixel signal because the sub-pixel at the top-left with respect to the microlens is the second sub-pixel SPX2. Referring to FIGS. 32 and 34, the second pixel PX2 may output a pixel signal based on the sub-pixel disposed at the top-left with respect to the microlens in the first readout operation RO21 and output a pixel signal based on all sub-pixels in the second readout operation RO22. The first pixel PX1 may output a pixel signal based on sub-pixels, excluding the second sub-pixel SPX2, in the second readout operation RO12.

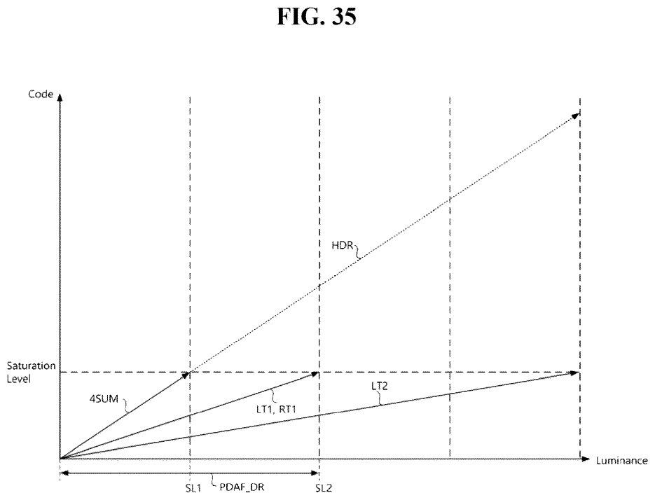

FIG. 35 is an example diagram illustrating the first phase data generated based on the operations of FIGS. 30 to 34.

Referring to FIG. 35, the first phase data PDT1 described with reference to FIGS. 1 to 9 may be generated based on image signals LT1 and RT1 based on the first sub-pixels output during the second readout operation RO12 of the first pixels PX1_1, PX1_2, PX1_3, and PX1_4 described with reference to FIGS. 30 to 34.

The first phase data PDT1 may be generated based on image signals LIS and RIS based on a subset of sub-pixels of the first pixel PX1, and thus may include accurate phase information at brightness levels lower than or equal to second light brightness SL2. However, the first phase data PDT1 of FIG. 35 may be generated based on image signals of two sub-pixels, so that the dynamic range of the first phase data PDT1 may be narrower than that in the embodiment of FIG. 29. For example, the first phase data PDT1 may include inaccurate phase information at brightness levels higher than the second light brightness SL2.

However, a high-illuminance range of the HDR image data may be generated based on an image signal obtained by amplifying the first image signal LT by a factor of four. Accordingly, HDR image data with an extended dynamic range may be provided. As described in FIG. 4, image signals based on the first pixel may be used for HDR image data after bad pixel correction.

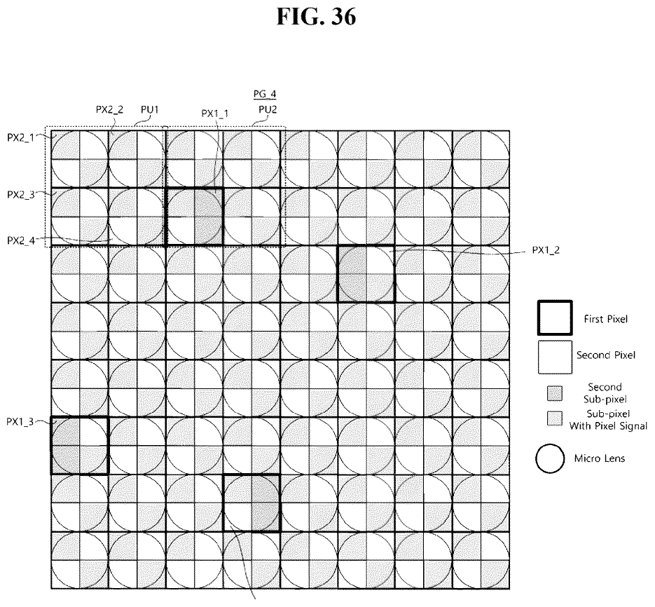

FIG. 36 is an example diagram illustrating a first readout operation of a pixel group including the first pixels PX1_A1 and PX1_A2 according to the embodiment of FIG. 9. The first readout operation of a pixel group PG_4 in the second mode may be the same as that in FIG. 13. Descriptions redundant to those of FIGS. 12, 13, and 21-28 are omitted. Each of the first pixels PX1_1, PX1_2, PX1_3, and PX1_4 of FIG. 36 may correspond to one of the first pixels PX1_A1 and PX1_A2 of FIG. 9.

FIG. 30 illustrates, in contrast to FIGS. 12 and 30, that in the first readout operation, the first pixels PX1_1, PX1_2, PX1_3, and PX1_4 and the second pixel PX2 may output a pixel signal based on sub-pixels disposed at the top-left and bottom-right with respect to a microlens. When the sub-pixel at the top-left or bottom-right of the first pixels PX1_1, PX1_2, PX1_3, and PX1_4 is a second sub-pixel SPX2, the first pixels PX1_1, PX1_2, PX1_3, and PX1_4 may not output a pixel signal for a subset of sub-pixels in the first readout operation. For example, in the first readout operation, the first pixels PX1_1 and PX1_4 may output a pixel signal for the sub-pixel at the top-left, and the first pixels PX1_2 and PX1_3 may output a pixel signal for the sub-pixel at the bottom-right.

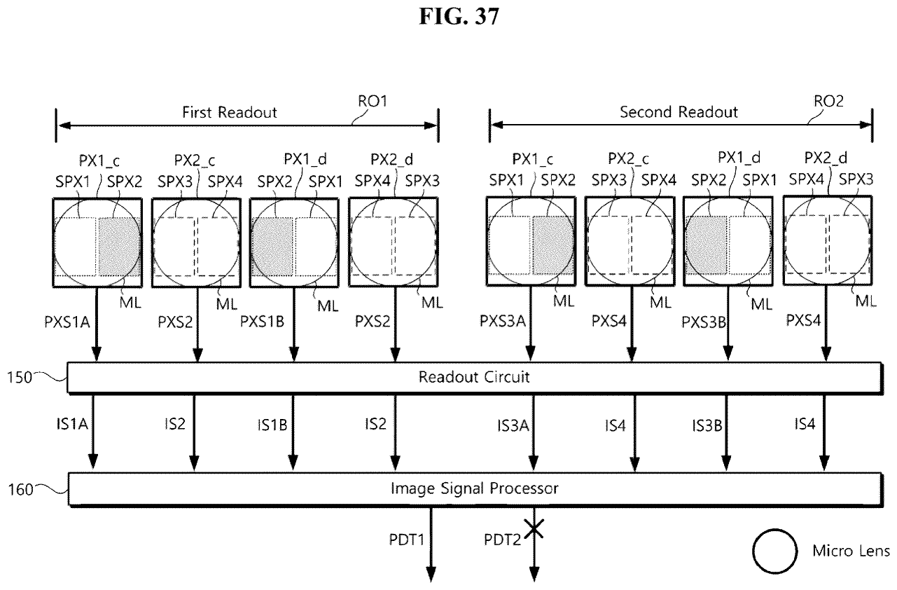

FIG. 37 is an example diagram illustrating a method of generating phase data based on a first readout according to the embodiment of FIG. 36 by an image signal processor. Descriptions similar or redundant to the method of generating phase data in FIG. 2 may be omitted. Each of the first pixels PX1_1, PX1_2, PX1_3, and PX1_4 of FIG. 36 may correspond to one of the first pixels PX1_c and PX1_d of FIG. 37. For example, the first pixels PX1_1 and PX1_4 of FIG. 36 may correspond to the first pixel PX1_c of FIG. 37, and the first pixels PX1_2 and PX1_3 of FIG. 36 may correspond to the first pixel PX1_d of FIG. 37.

FIG. 37, in contrast to FIG. 3, illustrates that both the first pixels PX1_c and PX1_d may output a pixel signal based on a single first sub-pixel in the first readout operation. For example, in the first readout operation, the first pixel PX1_c may output a pixel signal PXSIA of the sub-pixel at the top-left, and the first pixel PX1_d may output a pixel signal PXS1B of the sub-pixel at the bottom-right. In the second readout operation, the first pixel PX1_c may output a pixel signal PXS3A of the sub-pixels at the top-left and bottom-left, and the first pixel PX1_d may output a pixel signal PXS3B of the sub-pixels at the top-right and bottom-right.

Referring to FIG. 37, an image signal processor may generate first phase data PDT1 based on image signals IS1A, IS1B, IS3A, and IS3B based on pixel signals PXS3A and PXS3B. The image signal processor may not generate second phase data PDT2 based on a second image signal IS2 and a fourth image signal IS4.

A high-illuminance range of HDR image data may be generated based on an image signal obtained by amplifying the first image signal IS2 by a factor of two, and a low-illuminance range of the HDR image data may be generated based on the second image signal IS4. As described in FIG. 4, image signals based on the first pixels PX1_c and PX1_d may be used for HDR image data after bad pixel correction.

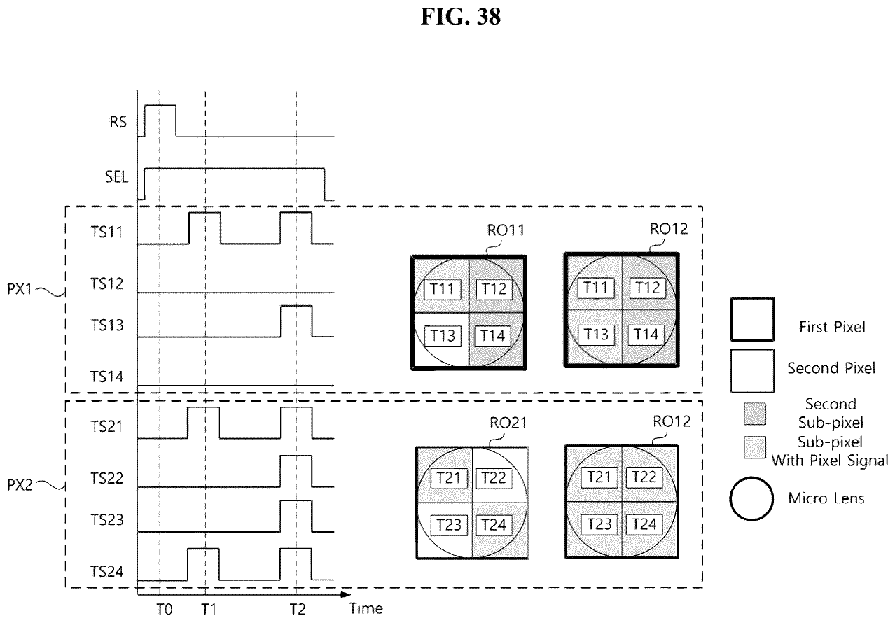

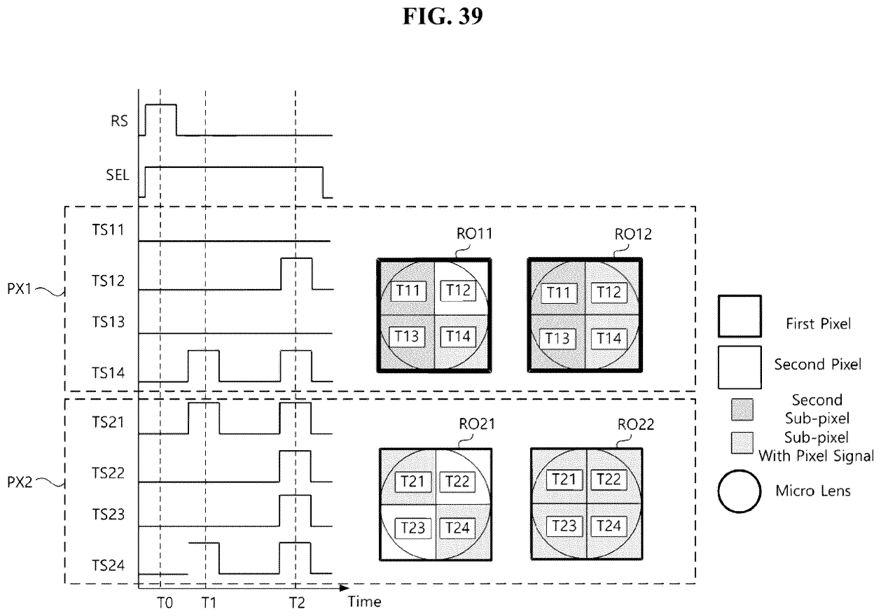

FIGS. 38 and 39 are example diagrams illustrating first readout operations RO11 and RO21 and second readout operations RO12 and RO22 of a pixel group PG_4 according to the embodiments of FIGS. 36 and 37. Descriptions redundant or similar to those of the above-described embodiments are omitted.

Referring to FIG. 38, the first pixels PX1_1 and PX1_4 may output a pixel signal of the sub-pixel at the top-left in the first readout operation RO11, and may output pixel signals of the sub-pixels on the left side in the second readout operation RO12. Referring to FIG. 39, the first pixels PX1_2 and PX1_3 may output a pixel signal of the sub-pixel at the bottom-right in the first readout operation RO11, and may output pixel signals of the sub-pixels on the right side in the second readout operation RO12.

Referring to FIGS. 38 and 39, the second pixels PX2 may output pixel signals of the sub-pixels at the top-left and bottom-right in the first readout operation RO21, and may output pixel signals of all sub-pixels in the second readout operation RO22.

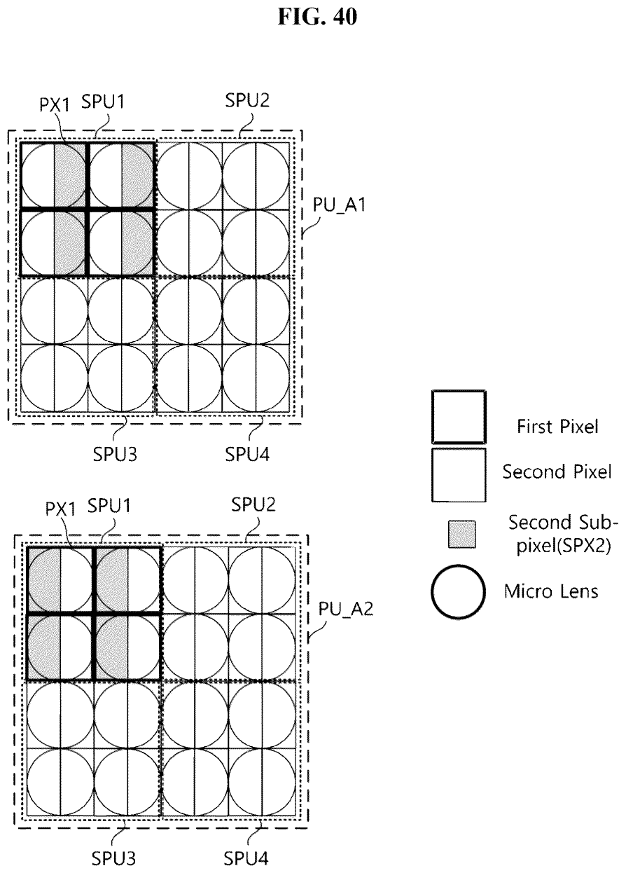

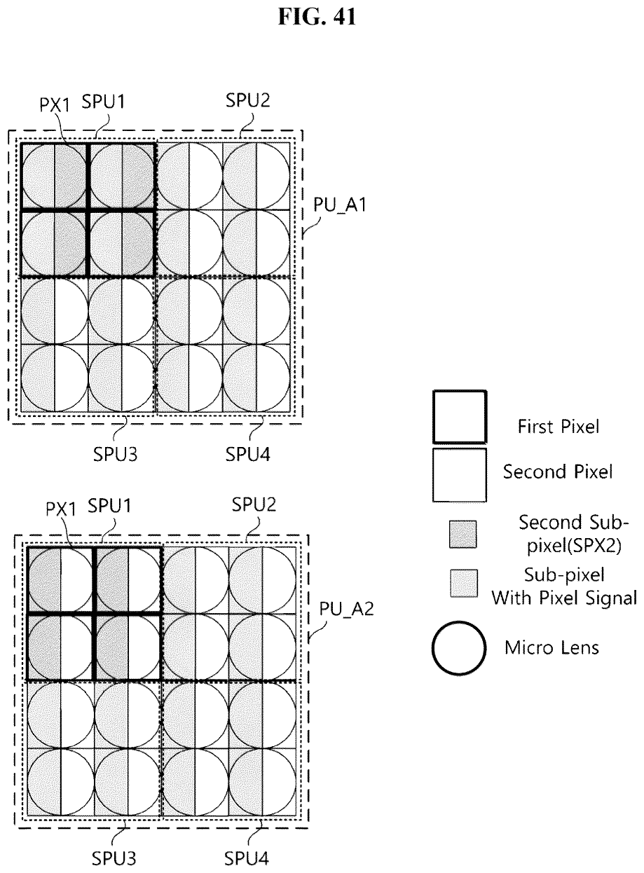

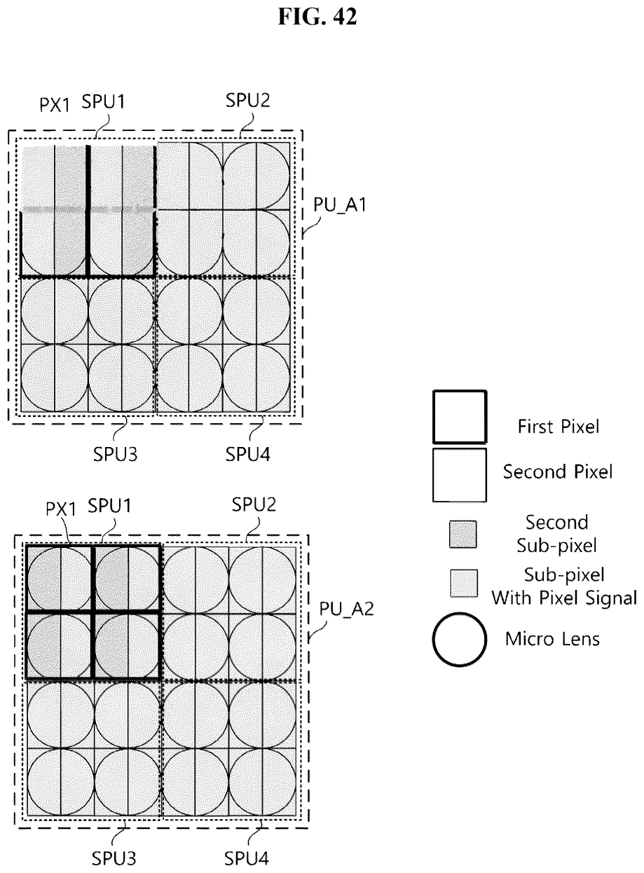

FIG. 40 is a diagram illustrating pixel units PU_A1 and PU_A2, each including a first pixel according to embodiments. FIGS. 41 and 42 are diagrams illustrating a first readout operation and a second readout operation of the pixel units PU_A1 and PU_A2 according to the embodiments of FIG. 40. The pixel units PU_A1 and PU_A2 may correspond to the pixel unit PU_A of FIG. 6A.

Referring to FIG. 40, among the pixels of the pixel units PU_A1 and PU_A2, each of the four pixels of the first pixel PX1 may include two sub-pixels sharing a microlens. With respect to the microlens, a sub-pixel on the left or right side of the four pixels of the first pixel PX1 may be a second sub-pixel.

Referring to FIG. 41, in the first readout operation, the first pixel PX1 of one of the pixel units PU_A1 and PU_A2 may not output a pixel signal. For example, in the first readout operation, the first pixel PX1 of the pixel unit PU_A1 may output a pixel signal based on the sub-pixel on the left side with respect to the microlens, while the first pixel PX1 of the pixel unit PU_A2 may not output a pixel signal.

Referring to FIG. 42, all pixels of the pixel units PU_A1 and PU_A2, excluding the second sub-pixel SPX2, may output pixel signals in the second readout operation.

The image signal processor 160 of FIG. 1 may generate the first phase data using image signals based on a pixel signals of the first pixel PX1 in the second readout operation.

A high-illuminance range of HDR image data may be generated based on an image signal obtained by amplifying a first image signal of the second pixel in the first readout operation by a factor of two, and a low-illuminance range of the HDR image data may be generated based on a second image signal of the second pixel in the second readout operation. As described in FIG. 4, image signals based on the first pixel PX1 may be used for HDR image data after bad pixel correction.

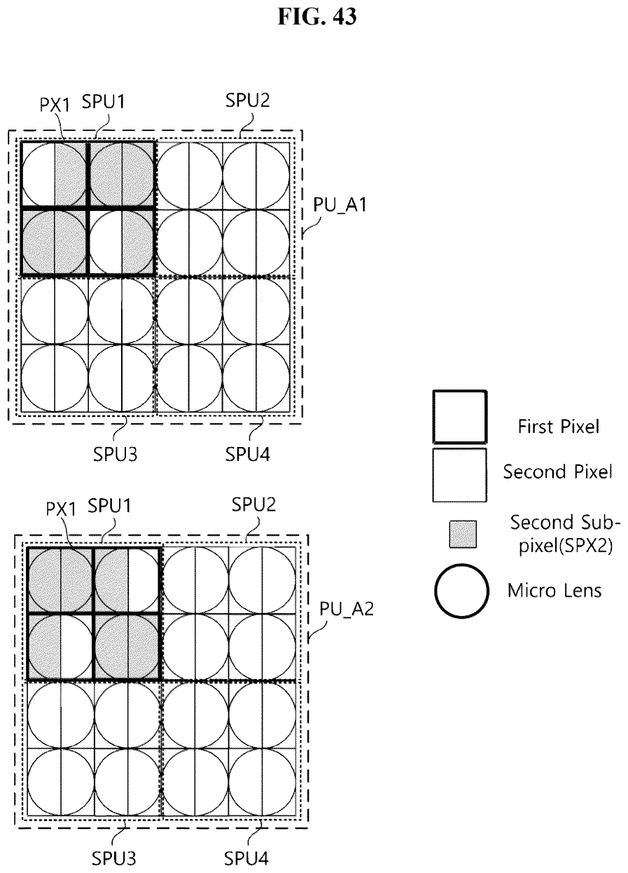

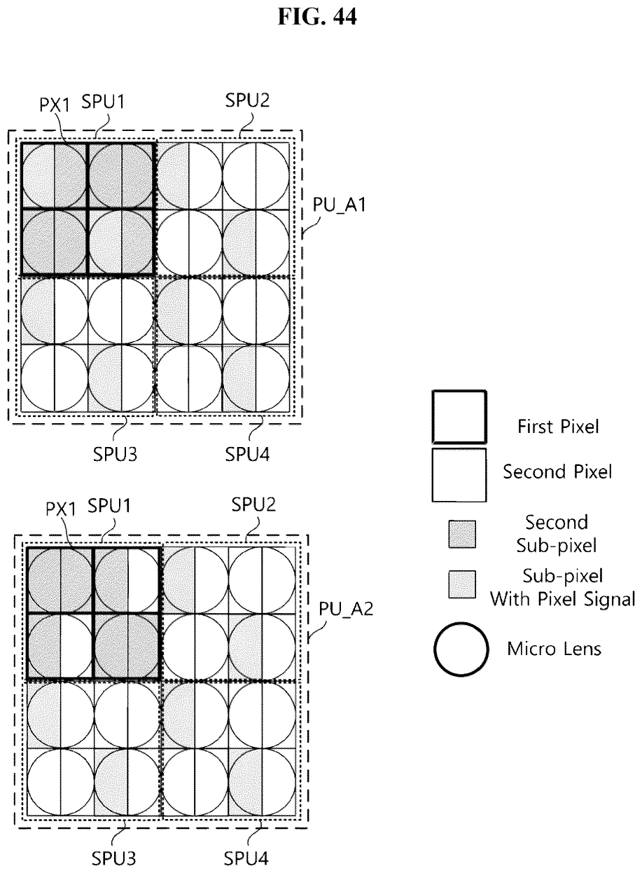

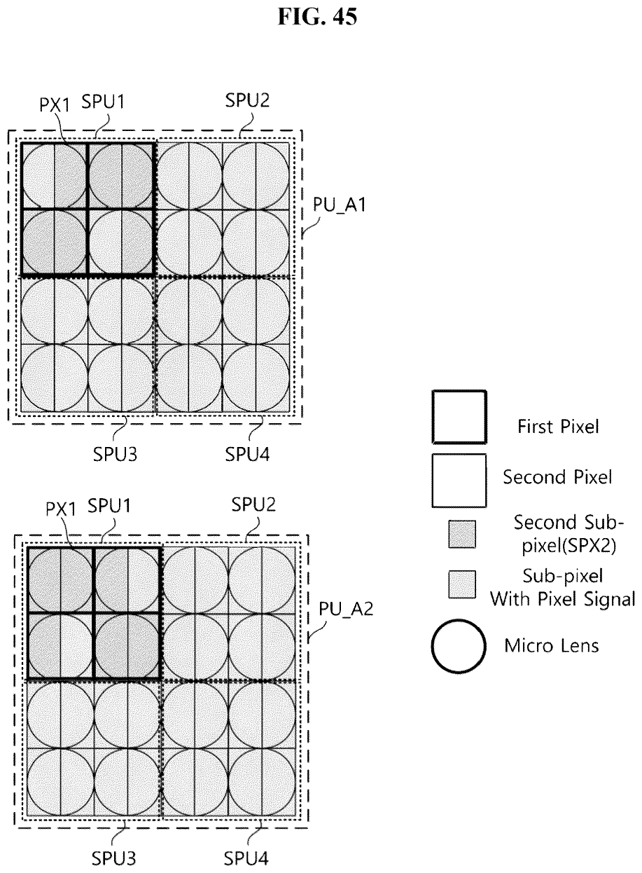

FIG. 43 is an example diagram illustrating pixel units PU_A1 and PU_A2, each including a first pixel according to one or more embodiments. FIGS. 44 and 45 are example diagrams illustrating a first readout operation and a second readout operation of the pixel units PU_A1 and PU_A2 according to the embodiments of FIG. 43. The pixel units PU_A1 and PU_A2 may correspond to the pixel unit PU_A of FIG. 6A.

Referring to FIG. 43, among the pixels of the pixel units PU_A1 and PU_A2, each of the four pixels of the first pixel PX1 may include two sub-pixels sharing a microlens. Among four pixels of the first pixel PX1, three sub-pixels may be second sub-pixels. For example, among the four pixels of the first pixel PX1, a single pixel in a diagonal direction of the sub-pixel unit SPU1 may have a single sub-pixel as a second sub-pixel SPX2, while sub-pixels of another pixel in another diagonal direction may be second sub-pixels SPX2.

Referring to FIG. 44, in the first readout operation, a first pixel PX1 of one of the pixel units PU_A1 and PU_A2 may not output a pixel signal. For example, in the first readout operation, the first pixel PX1 of the pixel unit PU_A1 may output a pixel signal based on a subset of sub-pixels on the left side with respect to the microlens, while the first pixel PX1 of the pixel unit PU_A2 may not output a pixel signal.

Referring to FIG. 44, in the first readout operation, the second pixel may output a pixel signal based on left sub-pixels of pixels in one diagonal direction.

Referring to FIG. 45, all pixels of the pixel units PU_A1 and PU_A2, excluding the second sub-pixel SPX2, may output pixel signals in the second readout operation.

The image signal processor 160 of FIG. 1 may generate the first phase data using image signals based on the pixel signals of the first pixel PX1 in the second readout operation.

A high-illuminance range of the HDR image data may be generated based on an image signal obtained by amplifying the first image signal of the second pixel in the first readout operation by a factor of four, and a low-illuminance range of the HDR image data may be generated based on the second image signal of the second pixel in the second readout operation. As described in FIG. 4, image signals based on the first pixel PX2 may be used for HDR image data after bad pixel correction.

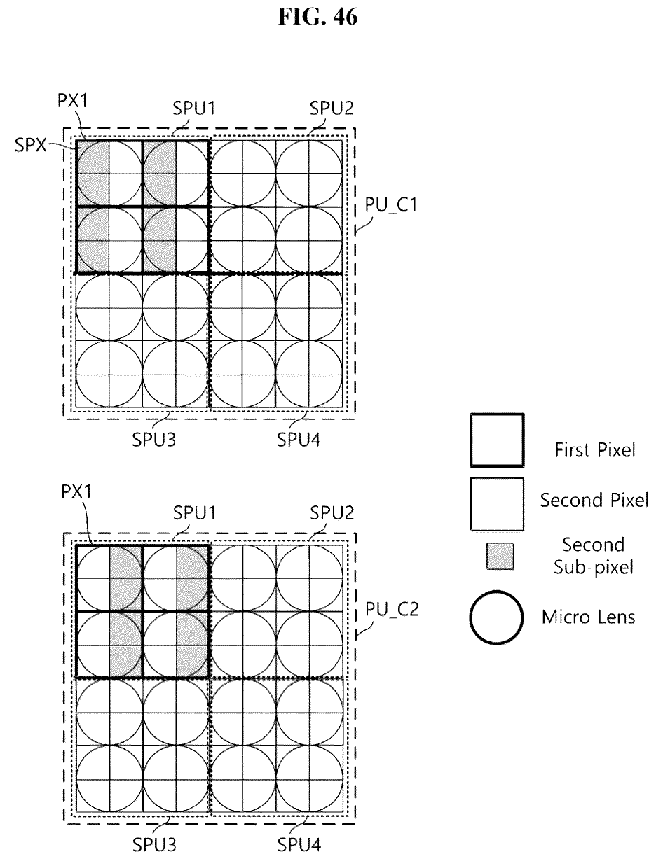

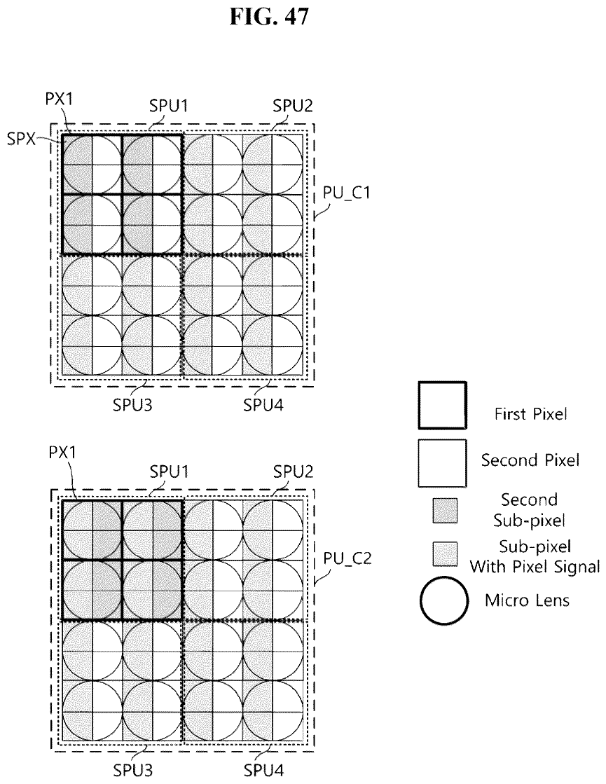

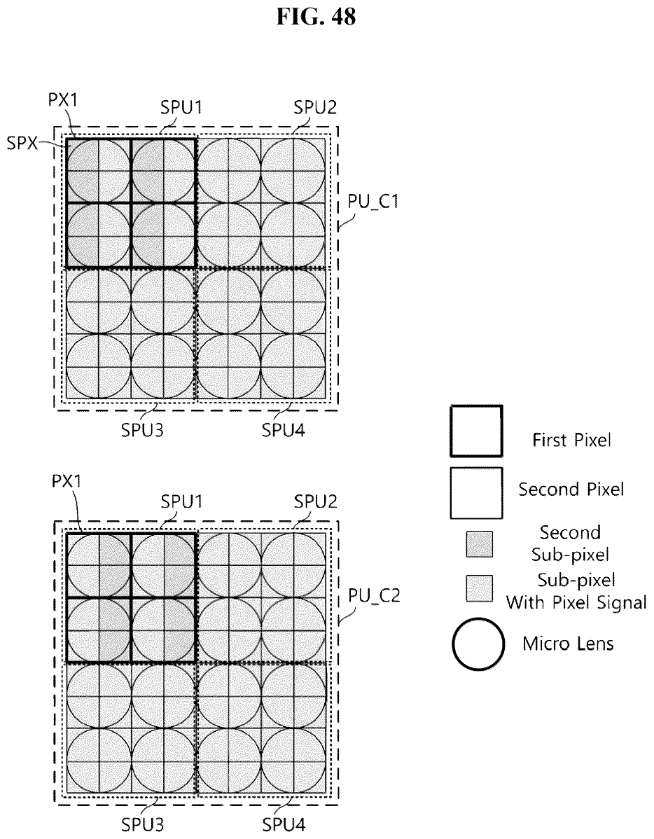

FIG. 46 is an example diagram illustrating pixel units PU_C1 and PU_C2, each including a first pixel according to one or more embodiments. FIGS. 47 and 48 are example diagrams illustrating a first readout operation and a second readout operation of the pixel units PU_C1 and PU_C2 according to the one or more embodiments of FIG. 46. The pixel units PU_C1 and PU_C2 may correspond to the pixel unit PU_C of FIG. 6C.

Referring to FIG. 46, among the pixels of the pixel units PU_C1 and PU_C2, each of the four pixels of the first pixel PX1 may include four sub-pixels sharing a microlens. With respect to the microlens, a sub-pixel on the left or right side of the four pixels of the first pixel PX1 may be a second sub-pixel.

Referring to FIG. 47, in the first readout operation, the first pixel PX1 of one of the pixel units PU_C1 and PU_C2 may not output a pixel signal. For example, in the first readout operation, the first pixel PX1 of the pixel unit PU_C1 may not output a pixel signal, while the first pixel PX1 of the pixel unit PU_C2 may output a pixel signal based on the sub-pixel on the left side with respect to the microlens.

Referring to FIG. 48, all pixels of the pixel units PU_C1 and PU_C2, excluding the second sub-pixel SPX2, may output pixel signals in the second readout operation.

The image signal processor 160 of FIG. 1 may generate the first phase data using image signals based on the pixel signals of the first pixel PX1 in the second readout operation.

A high-illuminance range of HDR image data may be generated based on an image signal obtained by amplifying the first image signal of the second pixel in the first readout operation by a factor of two, and a low-illuminance range of the HDR image data may be generated based on the second image signal of the second pixel in the second readout operation. As described in FIG. 4, image signals based on the first pixel PX1 may be used for HDR image data after bad pixel correction.

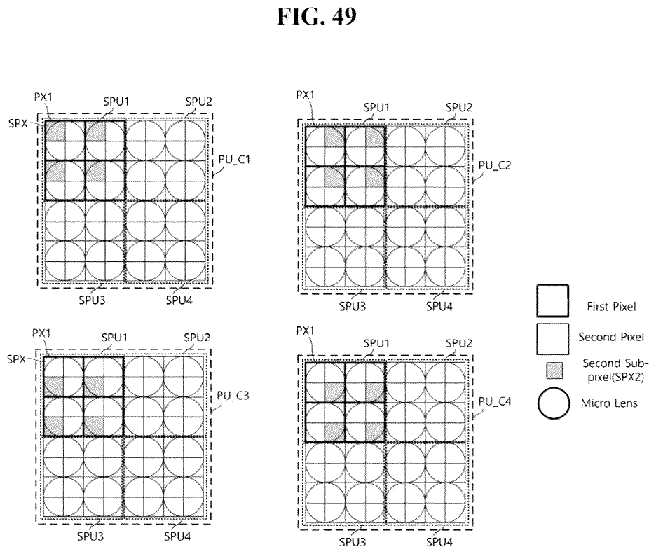

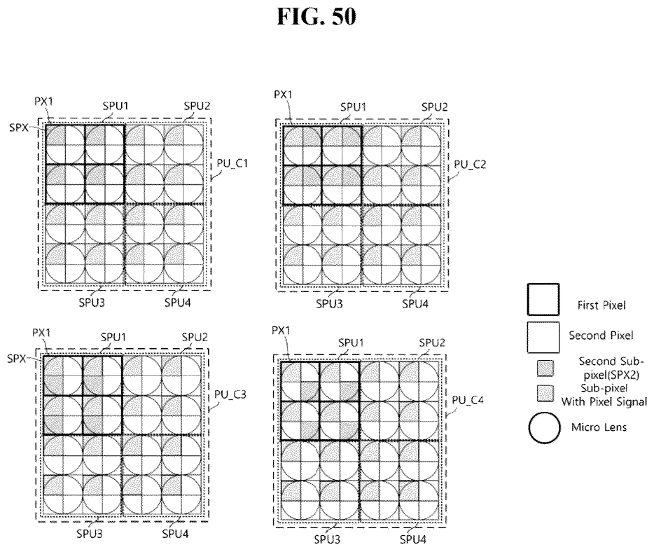

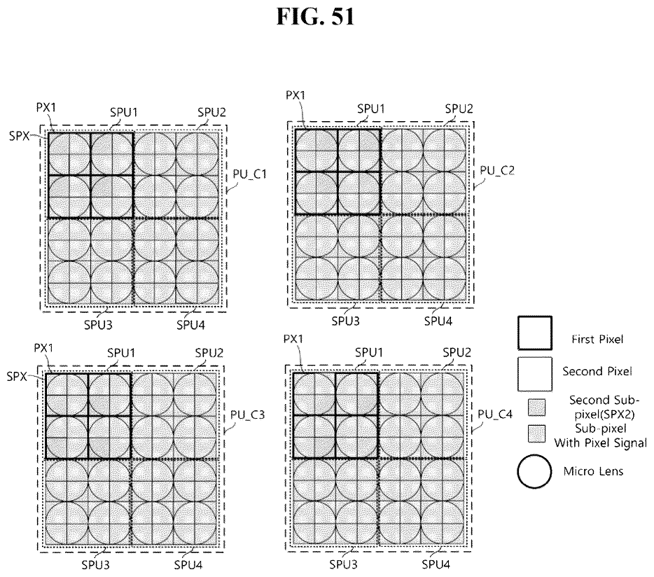

FIG. 49 is an example diagram illustrating pixel units PU_C1, PU_C2, PU_C3, and PU_C4, each including a first pixel according to embodiments. FIGS. 50 and 51 are example diagrams illustrating a first readout operation and a second readout operation of the pixel units PU_C1, PU_C2, PU_C3, and PU_C4 according to the embodiments of FIG. 49. The pixel units PU_C1, PU_C2, PU_C3, and PU_C4 may correspond to the pixel unit PU_C of FIG. 6C.

Referring to FIG. 49, among the pixels of the pixel units PU_C1, PU_C2, PU_C3, and PU_C4, each of the four pixels of the first pixel PX1 may include four sub-pixels sharing a microlens. With respect to the microlens, one of the sub-pixels of the four pixels of the first pixel PX1 may be a second sub-pixel.

Referring to FIG. 50, in the first readout operation, a first pixel PX1 of one of the pixel units PU_C1, PU_C2, PU_C3, and PU_C4 may not output a pixel signal. For example, in the first readout operation, the first pixel PX1 of the pixel unit PU_C1 may not output a pixel signal, while the first pixels PX1 of the pixel units PU_C2, PU_C3, and PU_C4 may output a pixel signal based on a sub-pixel at the top-left with respect to the microlens.

Referring to FIG. 50, the second pixel may output a pixel signal based on the sub-pixel at the top-left.

Referring to FIG. 51, all pixels of the pixel units PU_C1, PU_C2, PU_C3, and PU_C4, excluding the second sub-pixel SPX2, may output pixel signals in the second read out operation.

The image signal processor 160 of FIG. 1 may generate the first phase data using image signals based on the pixel signals of the first pixel PX1 in the second readout operation.

A high-illuminance range of HDR image data may be generated based on an image signal obtained by amplifying the first image signal of the second pixel in the first readout operation by a factor of four, and a low-illuminance range of the HDR image data may be generated based on the second image signal of the second pixel in the second readout operation. As described in FIG. 4, image signals based on the first pixel PX1 may be used for HDR image data after bad pixel correction.

As set forth above, according to embodiments, an image sensor may generate HDR images and reliably generate phase data across a wide dynamic range.

While various embodiments have been shown and described above, it will be apparent to those skilled in the art that modifications and variations could be made without departing from the scope of the present inventive concept as defined by the appended claims.

At least one of the components, elements, modules, units, or any nominalized verb (collectively “components” in this paragraph) represented by a block or an equivalent indication in the drawings including FIGS. 1-5, 7, and 37 may be implemented or embodied by analog and/or digital circuits including one or more of a logic gate, an integrated circuit, a microprocessor, a microcontroller, a memory circuit, a passive electronic component, an active electronic component, an optical component, and the like. Alternatively or additionally, these components may be implemented or embodied by software including one or more instructions stored in an internal or external storage medium (e.g., non-transitory) that is readable by at least one processor. For example, the at least one processor may invoke at least one of the one or more instructions stored in the storage medium, and execute it, with or without using one or more other components under the control of the at least one processor. This allows the at least one processor to perform at least one function or operation described above as being performed by each of the components according to the at least one instruction invoked. Here, the at least one processor may include a central processing unit (CPU), a graphic processing unit (GPU), another type of microprocessor, not being limited thereto. The at least one processor may be implemented as an application-specific integrated circuit (ASIC) or field-programmable gate array (FPGA).

What is claimed is:

1. An image sensor comprising:
a pixel array comprising a plurality of pixels;
a readout circuit configured to digitally convert pixel signals of the plurality of pixels to a plurality of image signals; and
an image processing circuit configured to output high dynamic range (HDR) image data and phase data based on the plurality of image signals, and
wherein:
the plurality of pixels comprises a first pixel and a second pixel;
each of the first pixel and the second pixel comprises sub-pixels sharing a microlens, each of the sub-pixels comprising a photoelectric element and a transfer transistor connecting the photoelectric element to a floating diffusion node; and
in each of the first pixel and the second pixel, a subset of sub-pixels at the same position with respect to the microlens, is configured to receive control signals of the transfer transistor through different interconnections.

2. The image sensor of claim 1, wherein:
the first pixel comprises a first sub-pixel and a second sub-pixel;
the second pixel comprises a third sub-pixel at a position corresponding to a position of the first sub-pixel, and a fourth sub-pixel at a position corresponding to a position of the second sub-pixel; and
each transfer transistor of the second sub-pixel and the fourth sub-pixel is configured to receive a transfer control signal through different interconnections.

3. The image sensor of claim 2, wherein:
each transfer transistor of the first sub-pixel and the third sub-pixel is configured to receive a transfer control signal through the same interconnection or different interconnections.

4. The image sensor of claim 2, wherein:
the first pixel comprises at least one first sub-pixel and at least one second sub-pixel; and
the second pixel comprises at least one third sub-pixel and at least one fourth sub-pixel.

5. The image sensor of claim 2, wherein:
the pixel array comprises different first pixels; and
second sub-pixels of the different first pixels are symmetric with respect to the microlens.

6. The image sensor of claim 2, wherein:
a number of second sub-pixels and a number of fourth sub-pixels are greater than or equal to a number of first sub-pixels and a number of third sub-pixels, respectively.

7. The image sensor of claim 2, wherein:
the image processing circuit is configured to output first phase data based on the first pixel and second phase data based on the first pixel and the second pixel.

8. The image sensor of claim 7, wherein:
the image processing circuit is configured to generate the second phase data further based on a first image signal, in which the second sub-pixel has been corrected for bad pixels, and a second image signal of the second pixel.

9. The image sensor of claim 1, wherein:
the first pixel comprises a first sub-pixel and a second sub-pixel;
the second pixel comprises a third sub-pixel and a fourth sub-pixel;
the pixel array is configured to output a first pixel signal based on the first sub-pixel during at least one of a first readout period and a second readout period, and not to output a pixel signal based on the second sub-pixel during the first readout period and the second readout period; and
the pixel array is configured to output a second pixel signal based on the third sub-pixel during the first readout period, and a third pixel signal based on both the third sub-pixel and the fourth sub-pixel during the second readout period.

10. The image sensor of claim 9, wherein:
the transfer transistor of the second sub-pixel is configured to be turned off during the first readout period and the second readout period.

11. The image sensor of claim 9, wherein:
the image processing circuit is configured to output first phase data based on the first pixel signal, and second phase data based on the first pixel signal, the second pixel signal, and the third pixel signal.

12. The image sensor of claim 11, wherein:
the image processing circuit is configured to generate the second phase data based further on one or more of the plurality of image signals in which the second sub-pixel has been corrected for bad pixels.

13. The image sensor of claim 1, wherein the image processing circuit comprises:
a bad pixel correction circuit configured to perform bad pixel correction on a second sub-pixel of the first pixel; and
an HDR processing circuit configured to generate the HDR image data based on one or more of the plurality of image signals in which the second sub-pixel has been corrected for bad pixels.

14. An image sensor comprising:
a pixel array comprising a plurality of pixels;
a readout circuit configured to digitally convert pixel signals of the plurality of pixels to image signals; and
an image processing circuit configured to output high dynamic range (HDR) image data and phase data based on the image signals, and
wherein:
the plurality of pixels comprises a first pixel and a second pixel;
each of the first pixel and the second pixel comprises sub-pixels sharing a microlens, each of the sub-pixels comprising a photoelectric element and a transfer transistor configured to connect the photoelectric element to a floating diffusion node;
at least one sub-pixel of the first pixel is configured not to output a pixel signal during both a first readout period and a second readout period; and
each sub-pixel of the second pixel is configured to output the pixel signal during at least one of the first readout period or the second readout period.

15. The image sensor of claim 14, wherein:
the image processing circuit is configured to output first phase data based on the first pixel and second phase data based on both the first pixel and the second pixel.

16. The image sensor of claim 15, wherein:
the image processing circuit is configured to generate the second phase data based on the image signals in which bad pixel correction was performed for a sub-pixel of the first pixel that did not output a pixel signal.

17. An image sensor comprising:
a pixel array comprising a plurality of pixel groups;
a readout circuit configured to digitally convert pixel signals from the pixel array to image signals; and
an image processing circuit configured to output high dynamic range (HDR) image data and phase data based on the image signals, and
wherein:
each of the plurality of pixel groups comprises a plurality of first pixels and a plurality of second pixels;
each of the plurality of first pixels and each of the plurality of second pixels comprises sub-pixels sharing a microlens, each of the sub-pixels comprising a photoelectric element and a transfer transistor connecting the photoelectric element to a floating diffusion node;
a first sub-pixel of each of the plurality of first pixels is configured to output a pixel signal during at least one of a first readout period and a second readout period, and a second sub-pixel of each of the plurality of first pixels is configured not to output a pixel signal during both the first readout period and the second readout period; and
sub-pixels of each of the plurality of second pixels are configured to output a pixel signal during at least one of the first readout period and the second readout period.

18. The image sensor of claim 17, wherein:
the plurality of first pixels comprises a third pixel and a fourth pixel; and
the first sub-pixel of the third pixel is disposed symmetric to the first sub-pixel of the fourth pixel with respect to the microlens.

19. The image sensor of claim 18, wherein:
each of the plurality of pixel groups comprises third pixels and fourth pixels; and
a number of the third pixels is equal to a number of the fourth pixels.

20. The image sensor of claim 17, wherein:
the plurality of first pixels comprises a third pixel, a fourth pixel, a fifth pixel, and a sixth pixel;
second sub-pixels of the third pixel and the fifth pixel are symmetric to first sub-pixels of the fourth pixel and the sixth pixel, respectively, in a row direction with respect to the microlens; and
second sub-pixels of the third pixel and the fourth pixel are symmetric to first sub-pixels of the fifth pixel and the sixth pixel, respectively, in both a column direction and the row direction with respect to the microlens.
